(19) United States
(12) Patent Application Publication
(10) Pub. No.: US 2023/0106477 A1
(43) Pub. Date: Apr. 6, 2023

(54) COMPOSITE, SLURRY COMPOSITION, FILM, AND METAL-CLAD LAMINATE

(71) Applicant: ENEOS CORPORATION, Tokyo (JP)

(72) Inventors: Shinichi KOMATSU, Tokyo (JP); Yoshihiro KUMAGAI, Tokyo (JP); Masaki NOGUCHI, Tokyo (JP); Hiroshi MATSUURA, Tokyo (JP)

(73) Assignee: ENEOS CORPORATION, Tokyo (JP)

(21) Appl. No.: 17/799,835

(22) PCT Filed: Feb. 16, 2021
(86) PCT No.: PCT/JP2021/005625

§ 371 Date: Aug. 15, 2022

(30) Foreign Application Priority Data
Feb. 21, 2020 (JP) 2020-027989

(51) Int. Cl. B32B 15/09; C09K 19/04; C09K 19/38

(52) U.S. Cl. CPC B32B 15/09; C09K 19/0403; C09K 19/3838; B32B 2457/08; C09K 2019/0407; C09K 2019/525

(57) ABSTRACT

A composite includes a liquid crystal polyester that is soluble in a solvent; and liquid crystal polymer particles that are insoluble in a solvent, have a melting point of 270° C. or more, and have a cumulative distribution 50% diameter D₅₀ of 20 μm or less and a cumulative distribution 90% diameter D₉₀ of 2.5 times or less the D₅₀ in a particle size distribution.

### TECHNICAL FIELD

The present invention relates to a composite, a slurry composition, a film, and a metal-clad laminate.

### BACKGROUND ART

In recent years, along with an increase in amounts of information communicated in the field of communications, the uses of signals having frequencies in high-frequency bands have been increasing in electronic devices, communication devices, and the like.

Particularly, signals having frequencies in gigahertz (GHz) band, that is, frequencies of 10⁹ Hz or more, have been frequently used. However, as the frequencies of signals to be used become higher, a decrease in quality of output signals, which would possibly cause false recognition of information, that is, a transmission loss increases. This transmission loss is basically considered to be due to a conductor loss, which is caused by conductors, and a dielectric loss, which is caused by resins for insulation used in electric and electronic components such as electronic circuit boards in electronic devices and communication devices. In view of such background, it has been studied to use resin composites that are excellent in dielectric property as resins for use in circuit boards.

For example, International Publication No. WO2017/150336 (PTL 1) discloses a composite comprising: at least one resin selected from the group consisting of a thermosetting resin and a thermoplastic resin; and liquid crystal polymer particles. However, such a composite as described in PTL 1 has not been satisfactory in terms of obtaining a slurry having a high dispersibility or in terms of having a lower dissipation factor.

### CITATION LIST

### Patent Literature

[PTL 1] International Publication No. WO2017/150336

### SUMMARY OF INVENTION

### Technical Problem

The present invention has been made in view of the above-described problem of the conventional techniques, and has an object to provide a composite that enables a slurry having a high dispersibility to be obtained and is capable of having a lower dissipation factor, a slurry composition using the same, a film comprising the composite, and a metal-clad laminate using the composite.

### Solution to Problem

As a result of conducting earnest studies in order to achieve the above object, the present inventors have found that a composite comprising: a liquid crystal polyester that is soluble in a solvent; and specific liquid crystal polymer particles described below enables a slurry having a high dispersibility to be obtained and is capable of having a lower dissipation factor, and completed the present invention.

Specifically, a composite of the present invention comprises:

a liquid crystal polyester that is soluble in a solvent; and

liquid crystal polymer particles that are insoluble in a solvent, have a melting point of 270° C. or more, and have a cumulative distribution 50% diameter D₅₀ of 20 μm or less and a cumulative distribution 90% diameter D₉₀ of 2.5 times or less the D₅₀ in a particle size distribution.

In addition, a slurry composition of the present invention comprises:

the above composite of the present invention; and

a solvent.

Moreover, a film of the present invention comprises:

the above composite of the present invention.

In addition, a metal-clad laminate of the present invention comprises:

a metal foil; and

a resin layer stacked on the metal foil, wherein

the resin layer is a layer comprising the above composite of the present invention.

### Advantageous Effects of Invention

The present invention makes it possible to provide a composite that enables a slurry having a high dispersibility to be obtained and is capable of having a lower dissipation factor, a slurry composition using the same, a film comprising the composite, and a metal-clad laminate using the composite.

### DESCRIPTION OF EMBODIMENTS

Hereinafter, the present invention will be described in detail based on preferred embodiments.

<Composite>

A composite of the present invention comprises:

a liquid crystal polyester that is soluble in a solvent; and

liquid crystal polymer particles that are insoluble in the solvent, have a melting point of 270° C. or more, and have a cumulative distribution 50% diameter D₅₀ of 20 μm or less and a cumulative distribution 90% diameter D₉₀ of 2.5 times or less the D₅₀ in a particle size distribution. First of all, the “liquid crystal polyester that is soluble in a solvent” and the “liquid crystal polymer particles” will be described below separately.

[Liquid Crystal Polyester That Is Soluble in a Solvent]

As describe above, the liquid crystal polyester according to the present invention is soluble in a solvent. Such a liquid crystal polyester only has to be soluble in a solvent, and a publicly-known liquid crystal polyester that has such properties (soluble) can be used as appropriate.

In addition, the liquid crystal polyester that is soluble in a solvent is preferably a liquid crystal polyester (hereinafter, sometimes referred to simply as a “liquid crystal polyester (I)”) comprising the following monomers (A) to (C):

[monomer (A)] a bifunctional aromatic hydroxycarboxylic acid;

[monomer (B)] a bifunctional aromatic dicarboxylic acid; and

[monomer (C)] at least one compound selected from the group consisting of a bifunctional aromatic diol, a bifunctional aromatic hydroxyamine, and a bifunctional aromatic diamine, in which

at least one of the monomer (B) and the monomer (C) contains a compound for forming a bent structural unit, and a content of the compound for forming a bentstructural unit is 20 to 40% by mol relative to a total molar amount of the monomers (A) to (C).

Such a monomer (A) is a bifunctional aromatic hydroxycarboxylic acid. Such a bifunctional aromatic hydroxycarboxylic acid is not particularly limited, and a publicly-known bifunctional aromatic hydroxycarboxylic acid that can be used for the production of liquid crystal polyesters can be used as appropriate. For example, a compound represented by a formula: HO—Ar—COOH (Ar represents a divalent aromatic group. Note that such an aromatic group may have a substituent.) can be used. Note that in an aromatic hydroxycarboxylic acid represented by such a formula: HO—Ar—COOH (in the formula, Ar represents a divalent aromatic group. Note that such an aromatic group may have a substituent.), Ar in the formula includes, for example, a phenylene group, a naphthylene group, a biphenylene group, a terphenylene group, and the like each of which may have a substituent. Note that a substituent which a divalent aromatic group as Ar may have is not particularly limited, and includes, for example, a fluorine atom, a chlorine atom, a bromine atom, a methyl group, an ethyl group, a propyl group, a trifluoromethyl group, a phenyl group, and the like.

As such a monomer (A), at least one compound selected from compounds represented by the following formula (1):

HO—Ar¹—COOH (1)

[in the formula, Ar¹ is a group selected from the group consisting of 1,4-phenylene, 1,4-naphthylene, 1,5-naphthylene, 2,7-naphthylene, 2,6-naphthylene, and 4,4′-biphenylene (more preferably, a group selected from the group consisting of 1,4-phenylene and 2,6-naphthylene) 0.1 can be favorably used from the viewpoint that it is possible to more efficiently achieve an expression of liquid crystallinity and a reduction in dissipation factor and the viewpoint of easiness of acquisition. Note that as such a compound represented by the formula (1), p-hydroxybenzoic acid, 1-hydroxy-4-naphthoic acid, 1-hydroxy-5-naphthoic acid, 2-hydroxy-7-naphthoic acid, 2-hydroxy-6-naphthoic acid, and 4-(4-hydroxyphenyl) benzoic acid are preferable. In addition, one of such monomers (A) may be used alone or two or more of them may be used in combination.

In addition, the monomer (B) is a bifunctional aromatic dicarboxylic acid. Such a bifunctional aromatic dicarboxylic acid is not particularly limited, and a publicly-known bifunctional aromatic dicarboxylic acid that can be used for the production of liquid crystal polyesters can be used as appropriate. For example, a compound represented by a formula: HOOC—Ar—COOH (Ar represents a divalent aromatic group. Note that such an aromatic group may have a substituent.) can be used. Note that in an aromatic dicarboxylic acid represented by such a formula: HOOC—Ar—COOH (in the formula, Ar represents a divalent aromatic group. Note that such an aromatic group may have a substituent.), Ar has the same meaning as described in the formula of the monomer (A). In addition, in such a monomer (B), Ar in the formula: HOOC—Ar—COOH is not particularly limited, but preferable examples of Ar include, for example, a group selected from groups represented by the following formulae:

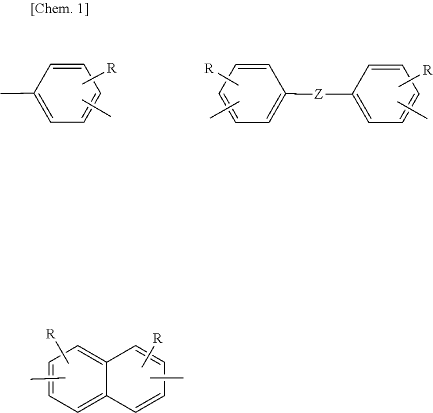

(in the formulae, R are each independently one selected from the group consisting of a hydrogen atom, a fluorine atom, a chlorine atom, a bromine atom, a methyl group, an ethyl group, a propyl group, a trifluoromethyl group, and a phenyl group, and Z is a single bond or a group selected from the group consisting of groups represented by formulae: —O—, —O—(CH₂)₂—O—, —O—(CH₂)₆—O—, —C(CF₃)₂, —CO—, and —SO₂—). Note that in the case of a compound in which carboxylic acids are bonded to adjacent carbon atoms in the Ar (a divalent aromatic group) (for example, in the case where Ar is a naphthylene, a compound substituted at the 1,2 positions, substituted at the 2,3 positions, or substituted at the 1,8 positions in which carboxyl acid groups are present adjacent to each other, or the like), there is a possibility that conversion to acid dianhydride proceeds in parallel during the production of a liquid crystal polyester depending on employed reaction conditions. For this reason, as the compound represented by the formula: HOOC—Ar—COOH, a compound in which carboxylic acids are not bonded to adjacent carbon atoms in Ar can be more favorably used.

In addition, as such a monomer (B), at least one compound selected from compounds represented by the following formula (2):

HOOC—Ar²—COOH (2)

[in the formula, Ar^{e} is a group which may have at least one substituent selected from the group consisting of a fluorine atom, a chlorine atom, a bromine atom, a methyl group, an ethyl group, a propyl group, a trifluoromethyl group, and a phenyl group and which is selected from the group consisting of 1,4-phenylene, 1,3-phenylene, 1,4-naphthylene, 1,5-naphthylene, 1,7-naphthylene (2,8-naphthylene), 1,3-naphthylene (2,4-naphthylene), 1,6-naphthylene (2,5-naphthylene), 2,6-naphthylene, 2,7-naphthylene, 4,4′-biphenylene, 4,4′-oxydiphenylene, 4,4′-carbonyldiphenylene, 4,4′-hexafluoroisopropylidene diphenylene, 4,4′-sulfonyldiphenylene, 4,4′-stilbene, and groups represented by the following formula (2-1):

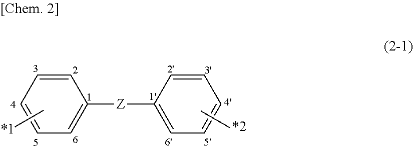

(in the formula, Z is a group selected from the group consisting a group represented by a formula: —O— (CH₂)₂—O— and a group represented by a formula: —O—(CH₂)₆—O—, and bonding arms represented by *1 and*2are bonded to 4,4′ positions, respectively.) (more preferably, a group which may have at least one substituent selected from the group consisting of a fluorine atom, a chlorine atom, a bromine atom, a methyl group, an ethyl group, a propyl group, a trifluoromethyl group, and a phenyl group and which is selected from the group consisting of 1,4-phenylene, 1,3-phenylene, 1,4-naphthylene, 1,5-naphthylene, 1,7-naphthylene (also known as: 2,8-naphthylene), 1,3-naphthylene (also known as: 2,4-naphthylene), 1,6-naphthylene (also known as: 2,5-naphthylene), 2,6-naphthylene, 2,7-naphthylene, and 4,4′-oxydiphenylene).] are preferable, from the viewpoint that it is possible to more efficiently achieve the expression of liquid crystallinity and the reduction in dissipation factor and the viewpoint that it is possible to more improve the solubility in a solvent.

Note that as described above, each group that can be selected as Ar² (including the groups represented by the formula (2-1)) may have at least one substituent selected from the group consisting of a fluorine atom, a chlorine atom, a bromine atom, a methyl group, an ethyl group, a propyl group, a trifluoromethyl group, and a phenyl group. That is, each group selected as the Ar^{e} may be a group in which a hydrogen atom is substituted with at least one of the substituents. As such a substituent, a methyl group, a phenyl group, and a trifluoromethyl group are more preferable, and a methyl group and a phenyl group are more preferable, because it is possible to achieve higher effects from the viewpoints of a reduction in dissipation factor and an improvement in solubility in a solvent.

In addition, as such a compound represented by the formula (2), terephthalic acid, isophthalic acid, 1,3-naphthalenedicarboxylic acid, 1,4-naphthalenedicarboxylic acid, 1,5-naphthalenedicarboxylic acid, 1,6-naphthalenedicarboxylic acid, 1,7-naphthalenedicarboxylic acid, 2,6-naphthalenedicarboxylic acid, 2,7-naphthalenedicarboxylic acid, 4,4′-biphenyldicarboxylic acid, diphenyl ether-4,4′-dicarboxylic acid (also called: 4,4′-dicarboxydiphenyl ether), benzophenone-4,4′-dicarboxylic acid, 2,2-bis(4-carboxyphenyl)hexafluoropropane, 4,4′-dicarboxydiphenyl sulfone, and 4,4′-stilbenedicarboxylic acid are more preferable, terephthalic acid, isophthalic acid, 1,4-naphthalenedicarboxylic acid, 1,5-naphthalenedicarboxylic acid, 2,6-naphthalenedicarboxylic acid, 2,7-naphthalenedicarboxylic acid, and diphenyl ether-4,4 ′-dicarboxylic acid are further preferable, and terephthalic acid, isophthalic acid, and 2,6-naphthalenedicarboxylic acid are particularly preferable, from the viewpoint that it is possible to more efficiently achieve the expression of liquid crystallinity and the reduction in dissipation factor and the viewpoint that it is possible to more improve the solubility in a solvent.

Note that in such a compound represented by the formula (2), the compound for forming a bent structural unit includes compounds represented by the formula (2) wherein Ar² is a group selected from the group consisting of 1,3-phenylene, 1,7-naphthylene (2,8-naphthylene), 1,3-naphthylene (2,4-naphthylene), 1,6-naphthylene (2,5-naphthylene), 4,4″-oxydiphenylene (a group represented by a formula: —C₆H₄—O—C₆H₄—[note that in the formula, C₆H₄ represents a phenylene group]), groups represented by the formula (2-1) wherein the Z is one selected from the group consisting of a group represented by a formula: —O—(CH₂)₂—O— and a group represented by a formula: —O—(CH₂)₆—O—, 4,4′-carbonyldiphenylene, 4,4′-hexafluoroisopropylidene diphenylene, and 4,4′-sulfonyldiphenylene. Here, the “compound for forming a bent structural unit” refers to, for example, a compound which makes it possible to form not a polymer chain having a straight linear structure but a chain bent by a structure derived from the compound when a structure in a liquid crystal polymer chain is formed using the compound, such as a compound having a structure portion like 1,3-phenylene, and which is used to form a structure portion (structural unit) bent in a polymer chain. On the other hand, in such a compound represented by the formula (2), a compound for forming a structure portion (structural unit) of straight line shape (a compound other than the compound for forming a bent structural unit) includes a compound represented by the formula (2) wherein Ar² is a group selected from the group consisting of 1,4-phenylene, 4,4 ′-biphenylene, 1,4-naphthylene, 1,5-naphthylene, 2,6-naphthylene, and 2,7-naphthylene.

In addition, among such compounds represented by the formula (2), 2,6-naphthalenedicarboxylic acid, isophthalic acid, terephthalic acid, 4,4″-biphenyldicarboxylic acid, 1,4-naphthalenedicarboxylic acid, 1,5-naphthalenedicarboxylic acid, and 2,7-naphthalenedicarboxylic acid are preferable, 2,6-naphthalenedicarboxylic acid, isophthalic acid, and terephthalic acid are more preferable, and 2,6-naphthalenedicarboxylic acid is particularly preferable, from the viewpoint that it is possible to more efficiently achieve the expression of liquid crystallinity and the reduction in dissipation factor and the viewpoint that it is possible to more improve the solubility in a solvent.

In addition, in a case where at least one of such compounds used as the monomer (B) is used as the compound for forming a bent structural unit, as the compound for forming a bent structural unit, isophthalic acid, 1,7-naphthalenedicarboxylic acid, 1,3-naphthalenedicarboxylic acid, 1,6-naphthalenedicarboxylic acid, and 4,4′-dicarboxydiphenyl ether are preferable, isophthalic acid, 1,7-naphthalenedicarboxylic acid, 1,3-naphthalenedicarboxylic acid, and 1,6-naphthalenedicarboxylic acid are more preferable, and isophthalic acid is particularly preferable, from the viewpoint that it is possible to more efficiently achieve the expression of liquid crystallinity and the reduction in dissipation factor and the viewpoint that it is possible to more improve the solubility in a solvent.

Moreover, the monomer (C) is at least one compound selected from the group consisting of a bifunctional aromatic diol, a bifunctional aromatic hydroxyamine, and a bifunctional aromatic diamine.

Such a bifunctional aromatic diol is not particularly limited, and a publicly-known bifunctional aromatic diol that can be used for the production of liquid crystal polyesters can be used as appropriate. For example, a compound represented by a formula: HO—Ar—OH (Ar represents a divalent aromatic group. Note that such an aromatic group may have a substituent) can be used. Note that in such an aromatic diol represented by the formula: HO—Ar—OH (in the formula, Ar represents a divalent aromatic group. Note that such an aromatic group may have a substituent), Ar has the same meaning as described in the formula of the monomer (A). In addition, in such a monomer (C), Ar in the formula: HO—Ar—OH is not particularly limited, but for example, a group selected from groups represented by the following formulae:

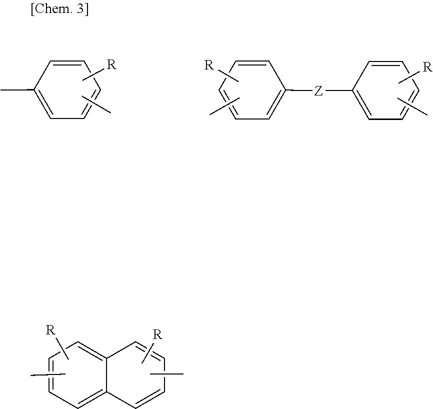

(in the formula, R are each independently one selected from the group consisting of a hydrogen atom, a fluorine atom, a chlorine atom, a bromine atom, a methyl group, an ethyl group, a propyl group, a trifluoromethyl group, and a phenyl group, and Z is a single bond or a group selected from the group consisting of groups represented by formulae: —O—, —CH₂—, —CH (CH₃)₂ (CH₃)₂—, C (CF₃)₂—, CPh₂-CO—, —S—, and —SO₂—. Note that regarding the group represented by the formula: —CPh₂-, Ph represents a phenyl group.) is preferable.

Moreover, as such a bifunctional aromatic diol used as the monomer (C), at least one compound selected from compounds represented by the following formula (3):

HO—Ar³—OH (3)

[in the formula, Ar³ is a group which may have at least one substituent selected from the group consisting of a fluorine atom, a chlorine atom, a bromine atom, a methyl group, an ethyl group, a propyl group, a trifluoromethyl group, and a phenyl group and which is selected from the group consisting of 1,4-phenylene, 1,3-phenylene, 1,2-phenylene, 1,2-naphthylene, 1,4-naphthylene, 1,5-naphthylene, 1,7-naphthylene (2,8-naphthylene), 1,8-naphthylene, 2,3-naphthylene, 1,3-naphthylene (2,4-naphthylene), 1,6-naphthylene (2,5-naphthylene), 2,6-naphthylene, 2,7-naphthylene, and groups represented by the following formula (3-1):

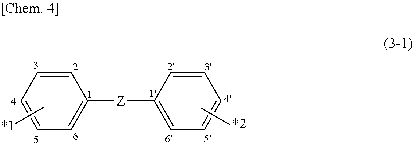

(in the formula, Z is a single bond or a group selected from the group consisting of groups represented by formulae: —O—, —CH₂—, —CH (CH₃)—, —C(CH₃)₂—, —C(CF₃)₂—, —CPh₂-, —CO—, and —SO₂—. Note that bonding arms represented by *1 and *2 are bonding arms bonded to OH groups in the formula (3), respectively.)] is preferable, from the viewpoint that it is possible to more efficiently achieve the expression of liquid crystallinity and the reduction in dissipation factor and the viewpoint that it is possible to more improve the solubility in a solvent. Note that as described above, each group that can be selected as Ar³ (including the groups represented by the formula (3-1)) may have at least one substituent selected from the group consisting of a fluorine atom, a chlorine atom, a bromine atom, a methyl group, an ethyl group, a propyl group, a trifluoromethyl group, and a phenyl group. That is, each group selected as the Ar^{a} may be a group in which a hydrogen atom is substituted with at least one of the substituents. As such a substituent, a methyl group, a phenyl group, and a trifluoromethyl group are more preferable, and a methyl group and a phenyl group are more preferable, because it is possible to achieve higher effects from the viewpoints of the reduction in dissipation factor and the improvement in solubility in a solvent.

In addition, as such a bifunctional aromatic diol, resorcinol, catechol, hydroquinone, 1,2-dihydroxynaphthalene, 1,4-dihydroxynaphthalene, 1,5-dihydroxynaphthalene, 1,7-dihydroxynaphthalene, 1,8-dihydroxynaphthalene, 2,3-dihydroxynaphthalene, 1,3-dihydroxynaphthalene, 1,6-dihydroxynaphthalene, 2,6-dihydroxynaphthalene, 2,7-dihydroxynaphthalene, 1,1′-bi-2-naphthol (BINOL), bisphenol fluorene, biscresol fluorene, methylhydroquinone (MHQ), phenylhydroquinone (PhHQ), and 1,4-dihydroxy-2-methylnaphthalene are more preferable, resorcinol, catechol, 2,3-dihydroxynaphthalene, BINOL, bisphenol fluorene, biscresol fluorene, MHQ, and PhHQ are further preferable, and resorcinol, catechol, and 2,3-dihydroxynaphthalene are particularly preferable, from the viewpoint that it is possible to more efficiently achieve the expression of liquid crystallinity and the reduction in dissipation factor and the viewpoint that it is possible to more improve the solubility in a solvent.

In addition, the bifunctional aromatic hydroxyamine that is used as the monomer (C) is not particularly limited, and a publicly-known bifunctional aromatic hydroxyamine that can be used for the production of liquid crystal polyester amides can be used as appropriate. For example, a compound represented by a formula: HO—Ar—NH₂ (in the formula, Ar represents a divalent aromatic group. Note that such an aromatic group may have a substituent) can be used. Note that in such an aromatic hydroxyamine represented by the formula: HO—Ar—NH₂ (Ar represents a divalent aromatic group. Note that such an aromatic group may have a substituent.), Ar has the same meaning as described in the formula of the monomer (A). In addition, as Ar in the formula: HO—Ar—NH₂, a group selected from groups represented by

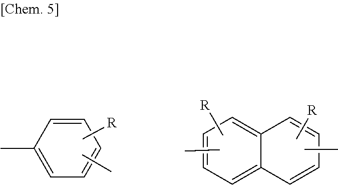

(in the formulae, R are each independently one selected from the group consisting of a hydrogen atom, a fluorine atom, a chlorine atom, a bromine atom, a methyl group, an ethyl group, a propyl group, a trifluoromethyl group, and a phenyl group) is preferable. Note that in the case of a compound in which a hydroxy group and an amino group are bonded to adjacent carbon atoms in Ar (a divalent aromatic group) (for example, in the case where Ar is a naphthylene, a compound substituted at the 1,2 positions, substituted at the 2,3 positions, or substituted at the 1,8 positions in which a hydroxy group and an amino group are present adjacent to each other, or the like), there is a possibility that conversion to oxazole proceeds in parallel depending on employed reaction conditions. For this reason, as the compound represented by the formula: HO—Ar—NH₂, a compound in which a hydroxy group and an amino group are not bonded to adjacent carbon atoms in Ar can be more preferably used.

In addition, as such a bifunctional aromatic hydroxyamine, at least one compound selected from compounds represented by the following formula (4):

HO—Ar⁴—NH₂ (4)

[in the formula, Ar⁴ is a group which may have at least one substituent selected from the group consisting of a fluorine atom, a chlorine atom, a bromine atom, a methyl group, an ethyl group, a propyl group, a trifluoromethyl group, and a phenyl group and which is selected from the group consisting of 1,4-phenylene, 1,3-phenylene, 1,4-naphthylene, 1,5-naphthylene, 1,7-naphthylene, 2,8-naphthylene, 1,3-naphthylene, 2,4-naphthylene, 1,6-naphthylene, 2,5-naphthylene, 2,6-naphthylene, and 2,7-naphthylene] is preferable, from the viewpoint that it is possible to more efficiently achieve the expression of liquid crystallinity and the reduction in dissipation factor and the viewpoint that it is possible to more improve the solubility in a solvent. Note that as described above, each group that can be selected as Ar⁴ may have at least one substituent selected from the group consisting of a fluorine atom, a chlorine atom, a bromine atom, a methyl group, an ethyl group, a propyl group, a trifluoromethyl group, and a phenyl group. That is, each group selected as the Ar⁴ may be a group in which a hydrogen atom is substituted with at least one of the substituents. As such a substituent, a methyl group, a phenyl group, and a trifluoromethyl group are more preferable, and a methyl group and a phenyl group are more preferable, because it is possible to achieve higher effects from the viewpoints of the reduction in dissipation factor and the improvement in solubility in a solvent.

As such a compound represented by the formula (4), 3-aminophenol, 4-aminophenol, 1-amino-5-naphthol (also called: 5-amino-1-naphthol), 8-amino-2-naphthol (also called: 1-amino-7-naphthol), 6-amino-1-naphthol (also called: 2-amino-5-naphthol), and 5-amino-2-naphthol (also called: 1-amino-6-naphthol) are preferable, 3-aminophenol, 4-aminophenol, 8-amino-2-naphthol, 6-amino-1-naphthol, 5-amino-2-naphthol, 6-methyl-3-aminophenol (6-Me-3-AP), and 3-methyl-4-aminophenol (3-Me-4-AP) are more preferable, 3-aminophenol, 4-aminophenol, 8-amino-2-naphthol, 6-Me-3-AP, and 3-Me-4-AP are further preferable, and 3-aminophenol, 4-aminophenol, and 8-amino-2-naphthol are particularly preferable, from the viewpoint that it is possible to more efficiently achieve the expression of liquid crystallinity and the reduction in dissipation factor and the viewpoint that it is possible to more improve the solubility in a solvent.

In addition, the bifunctional aromatic diamine that is used as the monomer (C) is not particularly limited, and a publicly-known bifunctional aromatic diamine that can be used for the production of liquid crystal polyester amides can be used as appropriate. For example, a compound represented by a formula: H₂N—Ar—NH₂ (in the formula, Ar represents a divalent aromatic group. Note that the divalent aromatic group may have a substituent.) can be used. Note that in such an aromatic diamine represented by the formula: H₂N—Ar—NH₂ (Ar represents a divalent aromatic group. Note that the divalent aromatic group may have a substituent.), Ar has the same meaning as described in the formula of the monomer (A). In addition, in such a monomer (C), Ar in the formula: H₂N—Ar—NH₂ is not particularly limited, but for example, a group selected from groups represented by the following formulae:

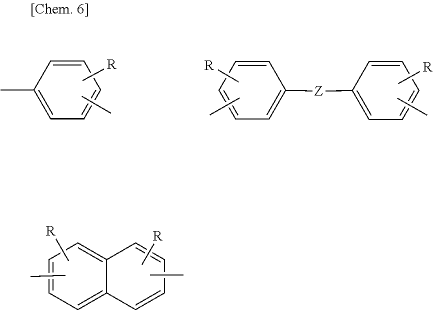

(in the formulae, R are each independently one selected from the group consisting of a hydrogen atom, a fluorine atom, a chlorine atom, a bromine atom, a methyl group, an ethyl group, a propyl group, a trifluoromethyl group, and a phenyl group, and Z is a single bond or a group selected from the group consisting of groups represented by formulae: —O—, —CH₂—, —CH (CH₃)₂ (CH₃)₂—, C (CF₃)₂—, CPh₂-CO—, —S—, and —SO₂—.) is preferable. Note that in the case of a compound in which amino groups are bonded to both of adjacent carbon atoms in Ar(a divalent aromatic group) (for example, in the case where Ar is a naphthylene, a compound substituted at the 1,2 positions, substituted at the 2,3 positions, or substituted at the 1,8 positions where two amino groups are present adjacent to each other, or the like) there is a possibility that conversion to imidazole proceeds in parallel depending on employed reaction conditions. For this reason, as the compound represented by the above-described formula: H₂N—Ar—NH₂, a compound in which amino groups are not bonded to both of adjacent carbon atoms in Ar can be more preferably used.

In addition, as the bifunctional aromatic diamine, at least one compound selected from compounds represented by the following formula (5):

H₂N—Ar³—NH₂ (5)

[in the formula, Ar³ is a group which may have at least one substituent selected from the group consisting of a fluorine atom, a chlorine atom, a bromine atom, a methyl group, an ethyl group, a propyl group, a trifluoromethyl group, and a phenyl group and which is selected from the group consisting of 1,4-phenylene, 1,3-phenylene, 1,4-naphthylene, 1,5-naphthylene, 1,7-naphthylene (2,8-naphthylene), 1,3-naphthylene (2,4-naphthylene), 1,6-naphthylene (2,5-naphthylene), 2,6-naphthylene, 2,7-naphthylene, 4,4′-oxydiphenylene, 3,4′-oxydiphenylene, 4,4′-biphenylene, 3,4′-biphenylene, and 3,3′-biphenylene.] is preferable, from the viewpoint that it is possible to more efficiently achieve the expression of liquid crystallinity and the reduction in dissipation factor and the viewpoint that it is possible to more improve the solubility in a solvent. Note that as such a compound represented by the formula (5), 1,4-phenylenediamine, 1,3-phenylenediamine, 1,4-diaminonaphthalene, 1,5-diaminonaphthalene, 1,7-diaminonaphthalene, 1,3-diaminonaphthalene, 1,6-diaminonaphthalene, 2,6-diaminonaphthalene, 2,7-diaminonaphthalene, 4,4′-diaminobenzanilide, 4,4′-oxydianiline, 3,4′-oxydianiline, 2,2′-bis(trifluoromethyl)benzidine, 9,9′-bis(4-aminophenyl)fluorene, benzidine, 2,2′-dimethyl-4,4′-diaminobiphenyl, 3,3′-dimethyl-4,4′-diaminobiphenyl, 4,4′-diphenyldiaminomethane, 4-aminophenyl-4-aminobenzoic acid, 4,4′-bis(4-aminobenzamide)-3,3′-dihydroxybiphenyl, 3,3′-diaminodiphenyl sulfone, 1,3-bis(3-aminophenoxy)benzene, 1,3-bis(4-aminophenoxy)benzene, 1,4-bis(4-aminophenoxy)benzene, 4,4′-bis(4-aminophenoxy)biphenyl, 4,4″-diamino-p-terphenyl, bis[4-(4-aminophenoxy)phenyl]sulfone, bis[4-(3-aminophenoxy)phenyl]sulfone, 2,2′-bis[4-(4-aminophenoxy)phenyl]propane, 2,2-bis[4-(4-aminophenoxy)phenyl]hexafluoropropane, bis[4-(4-aminophenoxy)phenyl]ketone, 4,4′-diaminodiphenyl sulfone, (2-phenyl-4-aminophenyl)-4-aminobenzoate, bis(4-aminophenyl)sulfide, bisaniline-M, bisaniline-P, bis(4-aminophenoxy)terephthalate, 2,2′″-diamino-p-quaterphenyl, 2,3′″-diamino-p-quaterphenyl, 2,4′″-diamino-p-quaterphenyl, 3,3′″-diamino-p-quaterphenyl, 3,4′″-diamino-p-quaterphenyl, and 4,4″′-diamino-p-quaterphenyl are more preferable, and 4,4′-oxydianiline, 1,4-phenylenediamine, 1,3-phenylenediamine, 1,4-diaminonaphthalene, 1,5-diaminonaphthalene, 2,6-diaminonaphthalene, 2,7-diaminonaphthalene, 3,4′-oxydianiline, and 1,3-bis(4-aminophenoxy)benzene are further preferable, from the viewpoint that it is possible to more efficiently achieve the expression of liquid crystallinity and the reduction in dissipation factor and the viewpoint that it is possible to more improve the solubility in a solvent.

Note that in the compounds represented by the above formulae (3) to (5), the compound for forming a bent structural unit includes, for example, compounds represented by the formulae wherein Ar³ to Ar⁵ in the formulae are each a group selected from the group consisting of 1,3-phenylene, 1,7-naphthylene (2,8-naphthylene), 1,3-naphthylene (2,4-naphthylene), and 1,6-naphthylene (2,5-naphthylene) (note that such a group may have at least one substituent selected from the group consisting of a fluorine atom, a chlorine atom, a bromine atom, a methyl group, an ethyl group, a propyl group, a trifluoromethyl group, and a phenyl group), and the like. On the other hand, in the compounds represented by the above formulae (3) to (5), the compound having a linear structure includes compounds represented by the formulae wherein Ar³ to Ar⁵ in the formulae are each a group selected from the group consisting of 1,4-phenylene, 4,4′-biphenylene, 1,4-naphthylene, 1,5-naphthylene, 2,6-naphthylene, and 2,7-naphthylene (note that such a group may have at least one substituent selected from the group consisting of a fluorine atom, a chlorine atom, a bromine atom, a methyl group, an ethyl group, a propyl group, a trifluoromethyl group, and a phenyl group).

In addition, in the case where at least one of such compounds used as the monomer (C) is used as the compound for forming a bent structural unit, as the compound for forming a bent structural unit, 3-aminophenol, 6-methyl-3-aminophenol, 1-amino-7-naphthol, catechol, resorcinol, 2,3-dihydroxynaphthalene, 1,3-phenylenediamine, and 1,7-diaminonaphthalene are preferable, and 3-aminophenol, 1-amino-7-naphthol, catechol, and 2,3-dihydroxynaphthalene are particularly preferable, from the viewpoint that it is possible to more efficiently achieve the expression of liquid crystallinity and the reduction in dissipation factor and the viewpoint that it is possible to more improve the solubility in a solvent.

In addition, the liquid crystal polyester (I) is a polymer comprising the above monomers (A) to (C). In other words, such a liquid crystal polyester (I) can be said to contain a structural unit (i) derived from the above monomer (A), a structural unit (ii) derived from the above monomer (B), and a structural unit (iii) derived from the above monomer (C).

As such a structural unit (i) derived from the above monomer (A), a structural unit represented by the following formula (i):

—O—Ar—CO— (i)

[in the formula, Ar represents a divalent aromatic group (note that it is more preferable that such Ar be identical to Ar¹ in the formula (1).). Note that the divalent aromatic group may have a substituent.] is preferable. In addition, as the structural unit (ii) derived from the above monomer (B), a structural unit represented by the following formula (ii):

—OC—Ar—CO— (ii)

[in the formula, Ar represents a divalent aromatic group (note that it is more preferable that such Ar be identical to Ar^{e} in the above formula (2)). Note that the divalent aromatic group may have a substituent.] is preferable. Moreover, as the structural unit (iii) derived from the above monomer (C), a structural unit represented by a formula out of the following formulae (iii) to (v):

—O—Ar—O— (iii)

—O—Ar—NH— (iv)

—HN—Ar—NH— (v)

[in each formula, Ar represents a divalent aromatic group (note that it is more preferable that Ar in the formula (iii) be identical to Ar³ in the above formula (3), it is more preferable that Ar in the formula (iv) be identical to Ar⁴ in the above formula (4), and it is more preferable that Ar in the formula (v) be identical to Ar⁵ in the above formula (4)). Note that the divalent aromatic group may have a substituent.] is preferable.

In such a liquid crystal polyester (I), the content of the monomer (A) is preferably 20 to 70% by mol, and more preferably 30 to 60% by mol, relative to the total molar amount of the monomers (A) to (C). When the content of the monomer (A) is within the above range, there is a tendency that it is possible to achieve higher effects in terms of the expression of liquid crystallinity, the reduction in dissipation factor, and the solubility in a solvent. In particular, setting the content of the monomer (A) to the lower limit or more makes it possible to more improve the effects such as the expression of liquid crystallinity and the reduction in dissipation factor, while setting the content of the monomer (A) to the upper limit or less makes it possible to more improve the solubility in a solvent.

In addition, in such a liquid crystal polyester (I), the content of the monomer (B) is preferably 10 to 50% by mol, and more preferably 20 to 40% by mol, relative to the total molar amount of the monomers (A) to (C). When the content of the monomer (B) is within the above range, there is a tendency that it is possible to achieve higher effects in terms of the expression of liquid crystallinity, the reduction in dissipation factor, and the solubility in a solvent. In particular, setting the content of the monomer (B) to lower limit or more makes it possible to more improve the solubility in a solvent, while setting the content of the monomer (B) to upper limit or less makes it possible to more improve the liquid crystallinity and the reduction in dissipation factor.

Moreover, in such a liquid crystal polyester (I), the content of the monomer (C) is preferably 10 to 50% by mol, and more preferably 20 to 40% by mol, relative to the total molar amount of the monomers (A) to (C). When the content of the monomer (C) is within the above range, there is a tendency that it is possible to achieve higher effects in terms of the expression of liquid crystallinity, the reduction in dissipation factor, and the solubility in a solvent. In particular, setting the content of the monomer (C) to the lower limit or more makes it possible to more improve the solubility in a solvent, while setting the content of the monomer (C) to the upper limit or less makes it possible to more improve the effects such as the expression of liquid crystallinity and the reduction in dissipation factor. Note that in the present invention, the preferable ranges of the contents of the respective structural units derived from the monomers (A) to (C) are the same as the above contents of the monomers (A) to (C).

Furthermore, in such a liquid crystal polyester (I), the total amount of the monomers (B) to (C) relative to 100 parts by mass of the monomer (A) is preferably 50 to 200 parts by mass (more preferably 55 to 190 parts by mass, and further preferably 60 to 180). When the total amount of the monomers (B) to (C) is within the above range, it becomes possible to more improve the expression of liquid crystallinity, the reduction in dissipation factor, and the solubility in a solvent. In particular, setting the total amount of the monomers (B) to (C) to the lower limit or more makes it possible to more improve the solubility in a solvent, while setting the total amount of the monomers (B) to (C) to the upper limit or less makes it possible to more improve the liquid crystallinity and the reduction in dissipation factor.

In addition, in the liquid crystal polyester (I) comprising the monomers (A) to (C), at least one of the monomer (B) and the monomer (C) contains a compound for forming a bent structural unit. In order to satisfy such a condition, for example, the monomer (A), the monomer (B) that contains a compound for forming a bent structural unit, and the monomer (C) that does not contain a compound for forming a bent structural unit may be used in combination, or the monomer (A), the monomer (B) that does not contain a compound for forming a bent structural unit, and the monomer (C) that contains a compound for forming a bent structural unit may be used in combination, or the monomer (A), the monomer (B) that contains a compound for forming a bent structural unit, and the monomer (C) that contains a compound for forming a bent structural unit may be used in combination. In addition, in the case of using the monomer (B) that contains a compound for forming a bent structural unit, the monomer (B) may include only of the compound for forming a bent structural unit, or may include the compound for forming a bent structural unit and another compound. Similarly, in the case of using the monomer (C) that contains a compound for forming a bent structural unit, the monomer (C) may include only of the compound for forming a bent structural unit, or may include the compound for forming a bent structural unit and another compound.

In this way, by using the compound for forming a bent structural unit as at least one of the “compound contained as the monomer (B)” which the liquid crystal polyester (I) comprises and the “compound contained as the monomer (C)” which the liquid crystal polyester (I) comprises, it is possible to cause a bending structure portion to be contained in the liquid crystal polyester (I), which makes it possible to express the liquid crystallinity and the solubility in a solvent. Note that as such a compound for forming a bent structural unit, it is possible to favorably use at least one compound selected from the group consisting of

compounds represented by the formula (2) wherein Ar^{e} is a group which may have at least one substituent selected from the group consisting of a fluorine atom, a chlorine atom, a bromine atom, a methyl group, an ethyl group, a propyl group, a trifluoromethyl group, and a phenyl group and which is selected from the group consisting of 1,3-phenylene, 1,7-naphthylene (2,8-naphthylene), 1,3-naphthylene (2,4-naphthylene), 1,6-naphthylene (2,5-naphthylene), and 4,4 ′-oxydiphenylene;

compounds represented by the formula (3) wherein Ar^{a} is a group which may have at least one substituent selected from the group consisting of a fluorine atom, a chlorine atom, a bromine atom, a methyl group, an ethyl group, a propyl group, a trifluoromethyl group, and a phenyl group and is selected from the group consisting of 1,3-phenylene, 1,2-phenylene, 3,4″-biphenylene, 3,3′-biphenylene, 2,2 ′-biphenylene, 1,2-naphthylene, 1,7-naphthylene (2,8-naphthylene), 1,8-naphthylene, 2,3-naphthylene, 1,3-naphthylene (2,4-naphthylene), 1,6-naphthylene (2,5-naphthylene), 2,7-naphthylene, groups represented by the formula (3-1) wherein the Z is a single bond and bonding arms represented by *1 and *2 are bonded to 3,4′ positions, 3,3′ positions, 3,2 ‘ positions, or 2,2’ positions, and groups represented by the formula (3-1) wherein Z is one selected from the group consisting of groups represented by formulae: —O—, —CH₂—, —CH (CH₃)—, —C(CH₃)₂—, —C(CF₃)₂—, —CPh₂-, —CO—, —S—, and —SO₂— (more preferably, a group selected from the group consisting of 1,3-phenylene, 1,2-phenylene, 2,3-naphthylene, 1,7-naphthylene (2,8-naphthylene), 1,3-naphthylene (2,4-naphthylene), and 1,6-naphthylene (2,5-naphthylene));

compounds represented by the formula (4) wherein Ar⁴ is a group which may have at least one substituent selected from the group consisting of a fluorine atom, a chlorine atom, a bromine atom, a methyl group, an ethyl group, a propyl group, a trifluoromethyl group, and a phenyl group and which is selected from the group consisting of 1,3-phenylene, 1,7-naphthylene, 2,8-naphthylene, 1,3-naphthylene, 2,4-naphthylene, 1,6-naphthylene, 2,7-naphthylene, and 2,5-naphthylene; and

compounds represented by the formula (5) wherein Ar⁵ is a group which may have at least one substituent selected from the group consisting of a fluorine atom, a chlorine atom, a bromine atom, a methyl group, an ethyl group, a propyl group, a trifluoromethyl group, and a phenyl group and which is selected from the group consisting of 1,3-phenylene, 3,4 ′-biphenylene, 3,3″-biphenylene, 1,7-naphthylene (2,8-naphthylene), 1,3-naphthylene (2,4-naphthylene), 1,6-naphthylene (2,5-naphthylene), and 2,7-naphthylene.

In addition, among such compounds for forming a bent structural unit, isophthalic acid (a type of the monomer (B)) diphenyl ether-4,4 ′-dicarboxylic acid (a type of the monomer (B)), 3-aminophenol (a type of the monomer (C)), 6-methyl-3-aminophenol (a type of the monomer (C)), 1-amino-7-naphthol (also called” 8-amino-2-naphthol”: a type of the monomer (C)), resorcinol (a type of the monomer (C)), bisphenol fluorene (a type of the monomer (C)), biscresol fluorene (a type of the monomer (C)), 2,3-dihydroxynaphthalene (a type of the monomer (C)), catechol (a type of the monomer (C)), and BINOL (also called“1,1″-bi-2-naphthol”: a type of the monomer (C)) are preferable, isophthalic acid, 3-aminophenol, and 1-amino-7-naphthol are more preferable, and 3-aminophenol and 1-amino-7-naphthol are particularly preferable, because it is possible to achieve higher effects from the viewpoints of the expression of liquid crystallinity, the reduction in dissipation factor, and the solubility in a solvent.

In addition, in such a liquid crystal polyester (I), the content of the compound for forming a bent structural unit is 20 to 40% by mol (more preferably 22 to 38% by mol, and further preferably 24 to 36% by mol) relative to the total molar amount of the monomers (A) to (C). When the content of the compound for forming a bent structural unit is within the above range, it becomes possible to more improve the expression of liquid crystallinity, the reduction in dissipation factor, and the solubility in a solvent. In particular, setting the content of the compound for forming a bent structural unit to the lower limit or more tends to more improve the solubility in a solvent, while setting the content of the compound for forming a bent structural unit to the upper limit or less tends to make it possible to more efficiently achieve the expression of liquid crystallinity and the reduction in dissipation factor.

When the content of the compound for forming a bent structural unit is set to 20 to 40% by mol relative to the total molar amount of the above monomers (A) to (C) in this way, a monomer unit (structural unit) derived from the compound for forming a bent structural unit is contained in the liquid crystal polyester (I) in a proportion of 20 to 40% by mol relative to the total amount of the monomer units which form the liquid crystal polymer chain. For this reason, the shape of the liquid crystal polymer obtained becomes not a straight line shape but a curved shape that is moderately bent. Since the structure of the liquid crystal polyester (I) has a curved shape that is moderately bent in this way, it is possible to dissolve the liquid crystal polyester (I) in a solvent, and it becomes possible to achieve the reduction in dissipation factor while expressing the liquid crystallinity.

In addition, as such a liquid crystal polyester (I) comprising the monomers (A) to (C), particularly liquid crystal polyesters formed by combining the monomers as exemplified in the following (1) to (12) are more preferable.

### Examples of Preferable Combinations of the Monomers (A) to (C)

(1) 2-hydroxy-6-naphthoic acid/2,6-naphthalenedicarboxylic acid/3-aminophenol
(2) 4-hydroxybenzoic acid/2,6-naphthalenedicarboxylic acid/3-aminophenol
(3) 2-hydroxy-6-naphthoic acid/isophthalic acid/4-aminophenol
(4) 2-hydroxy-6-naphthoic acid/isophthalic acid/3-aminophenol
(5) 2-hydroxy-6-naphthoic acid/2,6-naphthalenedicarboxylic acid/1-amino-7-naphthol
(6) 2-hydroxy-6-naphthoic acid/2,6-naphthalenedicarboxylic acid/bisphenol fluorene
(7) 2-hydroxy-6-naphthoic acid/2,6-naphthalenedicarboxylic acid/biscresol fluorene
(8) 2-hydroxy-6-naphthoic acid/2,6-naphthalenedicarboxylic acid/BINOL
(9) 2-hydroxy-6-naphthoic acid/isophthalic acid/1-amino-7-naphthol
(10) 4-hydroxybenzoic acid/2,6-naphthalenedicarboxylic acid/1-amino-7-naphthol
(11) 2-hydroxy-6-naphthoic acid/terephthalic acid/1-amino-7-naphthol
(12) 2-hydroxy-6-naphthoic acid/terephthalic acid/3-aminophenol
(13) 2-hydroxy-6-naphthoic acid/isophthalic acid/methylhydroquinone
(14) 2-hydroxy-6-naphthoic acid/diphenyl ether-4,4′-dicarboxylic acid/methylhydroquinone.

In addition, as such a liquid crystal polyester that is soluble in a solvent, a liquid crystal polyester (hereinafter, sometimes referred to simply as a “liquid crystal polyester (II)”) wherein a linear liquid crystal polymer chain comprising the monomers (A) to (C), in which at least one of the monomer (B) and the monomer (C) contains a compound for forming a bent structural unit, and a content of the compound for forming a bent structural unit is 20 to 40% by mol relative to a total molar amount of the monomers (A) to (C), is bonded via the following monomer (D):

[monomer (D)] an aromatic compound having 3 to 8 functional groups of at least one kind selected from the group consisting of a hydroxy group, a carboxy group, and an amino group, and a content proportion of the monomer (D) is 0.01 to 10% by mol relative to 100 mol of the total molar amount of the monomers (A) to (C) is more preferable.

The linear liquid crystal polymer chain in such a liquid crystal polyester (II) is a portion composed of the liquid crystal polyester (I). Favorable conditions for such a linear liquid crystal polymer chain (for example, favorable conditions for the monomers (A) to (C), the compound for forming a bent structural unit, and contents of these, and the like) are the same as the favorable conditions for the liquid crystal polyester (I). Note that as the monomer (C) which the linear liquid crystal polymer chain in such a liquid crystal polyester (II) comprises, the above-described ones can be used as appropriate, but among those, at least one compound selected from the group consisting of a bifunctional aromatic diol and a bifunctional aromatic hydroxyamine is more preferable from the viewpoints of the expression of liquid crystallinity, the reduction in dissipation factor, and the solubility in a solvent.

In addition, such a monomer (D) is an aromatic compound having 3 to 8 functional groups of at least one kind selected from the group consisting of a hydroxy group, a carboxy group, and an amino group. In such an aromatic compound having 3 to 8 functional groups, as the functional groups, a hydroxy group and a carboxy group are preferable, because it is possible to achieve higher effects from the viewpoints of the expression of liquid crystallinity, the reduction in dissipation factor, and the solubility in a solvent.

As such a monomer (D), for example, a compound represented by the following general formula (I):

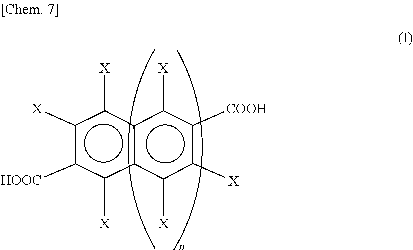

(in the formula, X each independently represent a hydroxy group (hydroxyl group), a carboxy group, an amino group, or a hydrogen atom, at least one of the plurality of X represents at least one functional group selected from the group consisting of a hydroxy group, a carboxy group, and an amino group, and n represents an integer of 0 to 2) and a compound represented by the following general formula (II):

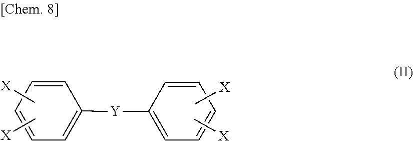

(in the formula, Y is a single bond or a group selected from the group consisting of groups represented by formulae: —O—, —CO—, —S—, —SO₂—, —CH₂—, —C(CH₃)₂—, and —C(CF₃)₂—, X each independently represent a hydroxy group (hydroxyl group), a carboxy group, an amino group, or a hydrogen atom, at least three of the plurality of X each represent at least one functional group selected from the group consisting of a hydroxy group, a carboxy group, and an amino group) can be favorably used.

In addition, as such an aromatic compound having 3 to 8 functional groups, for example, 2,5-dihydroxyterephthalic acid (DHTPA), 1,5-dihydroxynaphthalene-2,6-dicarboxylic acid (DONDC), 1,6-dihydroxynaphthalene-2,5-dicarboxylic acid, 1,4-dihydroxy-2-naphthoic acid, tetrahydroxyterephthalic acid, 1,3,5-benzenetricarboxylic acid (also called: trimesic acid (BTCA)), 3,5-dihydroxybenzoic acid (also called: α-resorcylic acid (DHBA)), 1,3,5-trihydroxybenzene (also called: phloroglucinol (BTOH)), benzenetetracarboxylic acid, benzenepentacarboxylic acid, benzenehexacarboxylic acid, naphthalenetricarboxylic acid, naphthalenetetracarboxylic acid, naphthalenepentacarboxylic acid, naphthalenehexacarboxylic acid, naphthaleneheptacarboxylic acid, naphthaleneoctacarboxylic acid, 5-hydroxyisophthalic acid (HIPA), diaminobenezene dicarboxylic acid, diaminonaphthalene dicarboxylic acid, dihydroxyanthracene dicarboxylic acid, diaminoanthracene dicarboxylic acid, 3,3′-dihydroxybenzidine, 4,6-dihydroxy-1,3-phenylenediamine, 4,4′-sulfonylbis(2-aminophenol), 4,4′-(propane-2,2-diyl)bis(2-aminophenol), 4,4′-(perfluoropropane-2,2-diyl)bis(2-aminophenol), 3,3′,4,4′-tetraaminodiphenyl ether, 5,5′-methylenebis (2-aminobenzoic acid), and the like are preferable.

Moreover, among such aromatic compounds having 3 to 8 functional groups, 3,5-dihydroxybenzoic acid, 1,3,5-trihydroxybenzene, 2,5-dihydroxyterephthalic acid, 1,5-dihydroxynaphthalene-2,6-dicarboxylic acid, 1,6-dihydroxynaphthalene-2,5-dicarboxylic acid, 1,4-dihydroxy-2-naphthoic acid, 1,3,5-benzenetricarboxylic acid, 5-hydroxyisophthalic acid, and benzenetetracarboxylic acid are more preferable, 2,5-dihydroxyterephthalic acid, 1,5-dihydroxynaphthalene-2,6-dicarboxylic acid, 1,6-dihydroxynaphthalene-2,5-dicarboxylic acid, 1,4-dihydroxy-2-naphthoic acid, and 1,3,5-benzenetricarboxylic acid are more preferable, 2,5-dihydroxyterephthalic acid, 1,5-dihydroxynaphthalene-2,6-dicarboxylic acid, and 1,6-dihydroxynaphthalene-2,5-dicarboxylic acid are further preferable, and 2,5-dihydroxyterephthalic acid is particularly preferable, because it is possible to achieve higher effects from the viewpoints of the expression of liquid crystallinity, the reduction in dissipation factor, and the solubility in a solvent.

In addition, such a liquid crystal polyester (II) is such that the linear liquid crystal polymer chain (a polymer chain composed of the liquid crystal polyester (I)) is bonded via the monomer (D). In such a liquid crystal polyester (II), a content proportion of the monomer (D) is 0.01 to 10 mol relative to 100 mol of the total molar amount of the monomers (A) to (C). That is, in such a liquid crystal polyester (II), in the case where the total molar amount of the monomers (A) to (C) is converted to 100 mol, it is preferable that the monomer (D) be contained in a proportion of 0.01 to 10 mol relative to 100 mol (converted value) of the total molar amount of the monomers (A) to (C). When the content proportion of such a monomer (D) is within the above range, there is a tendency that it is possible to achieve higher effects in terms of the reduction in dissipation factor and the solubility in a solvent. In particular, setting the content proportion of the monomer (D) to the lower limit or more tends to make it possible to more efficiently achieve the reduction in dissipation factor, and to more improve the pot life (working life) of an obtained slurry, while setting the content proportion of the monomer (D) to the upper limit or less tends to achieve a higher solubility.

In addition, in such a liquid crystal polyester (II), it is preferable to set the content proportion of the monomer (D) (the content proportion of a structural unit derived from the monomer (D)) to 0.01 to 10 mol relative to 100 mol of the total molar amount of the monomers (A) to (C). In a case where the content proportion of the monomer (D) is reduced (for example, in a case where the content proportion of the monomer (D) is set to about 5 mol or less relative to 100 mol of the total molar amount of the monomers (A) to (C)), it is considered that it is possible to make the structure in which the linear liquid crystal polymer chain is bonded via the monomer (D) into a multi-branched structure such as a so-called dendrimer (hyperbranched polymer or starburst polymer), that is, a multi-branched structure in which the center molecule (core) is derived from the monomer (D) and the linear liquid crystal polymer chains become side chains bonded to the core. Note that since the monomer (D) is a polyfunctional monomer, a multi-branched structure can be formed using the monomer (D) as the center molecule depending on the number of functional groups of the monomer (D). In addition, in a case where the content proportion of the monomer (D) is set to be relatively large within the range of 0.01 to 10 mol relative to 100 mol of the total molar amount of the monomers (A) to (C) (for example, in a case where the content proportion of the monomer (D) is set to about 6 mol or more relative to 100 mol of the total molar amount of the monomers (A) to (C)), it is considered that a net-shaped structure can be formed at least partially. Note that the present inventors assume that in a case where the content proportion of the monomer (D) is set to an amount (proportion) exceeding 10 mol relative to 100 mol (converted value) of the total molar amount of the monomers (A) to (C) in the liquid crystal polyester, a net-shaped structure thus formed becomes dense, with which the solubility in a solvent tends to decrease.

Here, from the viewpoint of achieving a lower value for the dissipation factor, and the viewpoint of more improving the solubility, the content proportion of the monomer (D) relative to 100 mol of the total molar amount of the monomers (A) to (C) is preferably 0.1 to 5 mol, and more preferably 0.5 to 4 mol. On the other hand, from the viewpoint of more improving the toughness and the solution stability (pot life) of the resin, the content proportion of the monomer (D) relative to 100 mol of the total molar amount of the monomers (A) to (C) is preferably 6 to 10 mol, and more preferably 7 to 9 mol.

In addition, in such a liquid crystal polyester (II), the total amount of the monomers (A) to (C) which the linear liquid crystal polymer chain comprises is preferably 90.0 to 99.9% by mol, and more preferably 93.0 to 99.4% by mol, relative to the total amount of the monomers (A) to (D). When the total amount of the monomers (A) to (C) (the content of the linear liquid crystal polymer chain) is within the above range, there is a tendency that the liquid crystal polyester has an excellent balance in terms of the expression of liquid crystallinity, the reduction in dissipation factor, and the solubility in a solvent.

In addition, such a liquid crystal polyester is soluble in a solvent. Note that in the Specification, when 4 g of the liquid crystal polyester is mixed with 16 g of N-methyl-2-pyrrolidone (NMP), followed by heating at 100° C. for 2 hours, if no solid component of the liquid crystal polyester is visually observed, it is determined that the liquid crystal polyester can be dissolved (soluble) in a solvent. On the other hand, if a solid component of the liquid crystal polyester is visually observed after the heating, it is determined that the liquid crystal polyester cannot be dissolved (insoluble) in a solvent.

Note that as a solvent in which the liquid crystal polyester of the present invention can be dissolved, an aprotic solvent is preferable, and the solvent is not limited to the above NMP. Such a solvent (preferably, an aprotic solvent) in which the liquid crystal polyester can be dissolved includes, for example, halogen solvents (1-chlorobutane, chlorobenzene, 1,1-dichloroethane, 1,2-dichloroethane, chloroform, 1,1,2,2-tetrachloroethane, and the like), ether solvents (diethyl ether, tetrahydrofuran, 1,4-dioxane, and the like), ketone solvents (acetone, cyclohexanone, and the like), ester solvents (ethyl acetate and the like), lactone solvents (γ-butyrolactone and the like), carbonate solvents (ethylene carbonate, propylene carbonate, and the like), amine solvents (triethylamine, pyridine, and the like), nitrile solvents (benzonitrile, acetonitrile, succinonitrile, and the like), amide solvents (N,N′-dimethylformamide, N,N′-dimethylacetamide, tetramethylurea, 1,3-dimethyl-2-imidazolidinone, N-methyl-2-pyrrolidone (NMP), and the like), nitro solvents (nitromethane, nitrobenzene, and the like), sulfide solvents (dimethyl sulfoxide, sulfolane, and the like), phosphoric acid solvents (hexamethylphosphoramide, tri-n-butyl phosphate, and the like), and phenol solvents (phenol, o-cresol, m-cresol, p-cresol, chlorophenol, bromophenol, methoxyphenol, and the like). One of these may be used alone or two or more of these may be used in combination. Among such solvents, N,N′-dimethylformamide, N,N′-dimethylacetamide, tetramethylurea, 1,3-dimethyl-2-imidazolidinone, or N-methyl-2-pyrrolidone (NMP) is more preferable, and N-methyl-2-pyrrolidone (NMP) is particularly preferable, from the viewpoint that a higher solubility can be achieved.

In addition, the liquid crystallinity of such a liquid crystal polyester can be checked by using polarized light microscopy. The liquid crystallinity can be checked, for example, by using a polarized light microscope manufactured by Olympus Corporation (under the trade name of BH-2) equipped with a hot stage for microscopes manufactured by Mettler Toledo (under the trade name of FP82HT), or the like and by heating and melting the liquid crystal polymer on the microscope hot-stage and observing the presence or absence of optical anisotropy.

In addition, as such a liquid crystal polyester (more preferably, the liquid crystal polyester (II)), the number average molecular weight (Mn) is preferably 10000 to 1000000, and more preferably 50000 to 500000, and the weight average molecular weight (Mw) is preferably 20000 to 2000000, and more preferably 100000 to 1000000. In addition, in the liquid crystal polyester (more preferably, the liquid crystal polyester (II)), a ratio (Mw/Mn) between the number average molecular weight (Mn) and the weight average molecular weight (Mw) is preferably within a range of 1.0 to 15.0 (more preferably 2.0 to 10.0). In the case where such Mn and Mw are within the above ranges, there is a tendency that it becomes possible to form a film and a metal-clad laminate which are more uniform and excellent in strength when the film is produced. Such molecular weights can be measured by a GPC (gel permeation chromatography) analysis. Note that as a specific measuring method, it is possible to employ the same method as the method employed in a method for measuring the number average molecular weights of the liquid crystal polyesters obtained in Examples described below.

Note that the method for producing such a liquid crystal polyester is not particularly limited, a publicly-known method can be employed to produce the liquid crystal polyester as appropriate. For example, in the case of producing the above liquid crystal polyester (I) or the above liquid crystal polyester (II), the liquid crystal polyester (I) or the liquid crystal polyester (II) can be produced by employing polymerization conditions (conditions for polycondensation) that are employed in a publicly-known method for producing polyester as appropriate except that the monomers (A) to (C) or (A) to (D) are used in a manner that satisfies the above-described conditions. Here, a method that can be preferably employed in order to produce the above liquid crystal polyester (II) will be briefly described.

As the method for producing such a liquid crystal polyester (II), for example, a method comprising: polycondensating a raw material mixture comprising the monomers (A) to (D), in which at least one of the monomer (B) and the monomer (C) contains a compound for forming a bent structural unit, a content of the compound for forming a bent structural unit is 20 to 40% by mol relative to a total molar amount of the monomers (A) to (C), and a content proportion of the monomer (D) is 0.1 to 10 mol relative to 100 mol of the total molar amount of the monomers (A) to (C), to obtain a liquid crystal polyester in which a linear liquid crystal polymer chain comprising the monomers (A) to (C) is bonded via the monomer (D) is preferable. By using such raw material compounds, it is possible to obtain the liquid crystal polyester (II) as a polycondensate of the raw material compounds. Note that conditions for the contents of the monomers (A) to (D) in such raw material compounds, conditions for the presence or absence and the content of the compound for forming a bent structural unit, and the like are the same conditions as the conditions described in the above liquid crystal polyesters (I) and (II).

Note that in such a raw material mixture, although the content proportion of the monomer (D) is set to 0.01 to 10 mol relative to 100 mol of the total molar amount of the monomers (A) to (C), particularly, the content proportion of the monomer (D) is more preferably 0.1 to 5 mol (further preferably 0.5 to 4 mol) relative to 100 mol of the total molar amount of the monomers (A) to (C) because a better balance can be achieved in terms of the expression of liquid crystallinity, the reduction in dissipation factor, and the solubility in a solvent. In addition, since it becomes possible to set the content of the monomer (A), the content of the monomer (B), and the content of the monomer (C) in the linear liquid crystal polymer chain in the obtained liquid crystal polyester to contents within the above-described preferable ranges, respectively, in the raw material mixture, the content of the monomer (A) relative to the total molar amount of the monomers (A) to (C) is preferably 20 to 70% by mol (more preferably 30 to 60% by mol), the content of the monomer (B) relative to the total molar amount of the monomers (A) to (C) is preferably 10 to 50% by mol (more preferably 20 to 40% by mol), and further the content of the monomer (C) relative to the total molar amount of the monomers (A) to (C) is preferably 10 to 50% by mol (more preferably 20 to 40% by mol). Moreover, the total amount of the monomers (B) to (C) relative to 100 parts by mass of the monomer (A) is preferably 50 to 200 parts by mass (more preferably 55 to 190 parts by mass, and further preferably 60 to 180 parts by mass). In addition, in such a raw material mixture, the content of the compound for forming a bent structural unit is 20 to 40% by mol (more preferably 22 to 38% by mol, and further preferably 24 to 36% by mol) relative to the total molar amount of the monomers (A) to (C). By setting the content of the compound for forming a bent structural unit within the above range, it becomes possible to more improve the expression of liquid crystallinity, the reduction in dissipation factor, and the solubility in a solvent.

In addition, it is preferable that the raw material mixture further contain an acid anhydride from the viewpoint of industrial production method (decarboxylation polymerization). As such an acid anhydride, acetic anhydride, propionic anhydride, butyric anhydride, and isobutyric anhydride are preferable. Among these, acetic anhydride is more preferable from the viewpoint of easiness of removing a condensate (carboxylic acid). Note that the content of such an acid anhydride is preferably 1.00 to 1.20 molar equivalent (more preferably 1.01 to 1.10 molar equivalent) relative to a hydroxyl group and an amino group in all the monomers (monomers (A) to (D)).

In addition, in such a raw material mixture, as necessary, a publicly-known additive component that can be used in polycondensation of polyester such as a catalyst, promoter, another monomer, a condensing agent, or an azeotropic solvent as appropriate. As such a catalyst, a conventionally publicly-known catalyst for polymerizing polyester can be used, and includes, for example, metallic salt catalysts such as magnesium acetate, stannous acetate, tetrabutyl titanate, lead acetate, sodium acetate, potassium acetate, and antimony trioxide: organic compound catalysts such as a nitrogen-containing heterocyclic compounds such as N-methylimidazole: and the like. The amount of such a catalyst to be used is not particularly limited, but is preferably 0.0001 to 0.1 parts by weight relative to 100 parts by mass of the total amount of the monomers.

In addition, in the present invention, when the raw material mixture is polycondensated (reacted), it is preferable to polycondensate the raw material mixture through melt polymerization from the viewpoint that it becomes possible to reduce the number of steps while it is possible to more improve the reaction efficiency and the yield of products. In addition, as reaction conditions for such polycondensation, publicly-known conditions used in formation of liquid crystal polyesters can be employed as appropriate depending on the types of monomers to be used, and is not particularly limited. However, it is preferable to polycondensate the raw material mixture through melt polymerization by reacting the raw material mixture under a temperature condition of 0 to 400° C. (more preferably 100 to 380° C.) for 0.1 to 100 hours.

In such polycondensation, it is preferable to employ a method that first reacts a raw material mixture under a first temperature condition of 100 to 400° C. (more preferably 120 to 380° C.) to form a polymer (prepolymer) having a low degree of polymerization, and then further reacts the raw material mixture under a second temperature condition of 150 to 400° C. (more preferably 160 to 380° C.) to polycondensate the raw material mixture through melt polymerization or solid phase polymerization from the viewpoint of improving the degree of polymerization and the physical properties. The reaction time under the first temperature condition is preferably 0.1 to 50 hours (more preferably 0.5 to 30 hours). In addition, the reaction time under the second temperature condition is preferably 0.5 to 50 hours (more preferably 1.0 to 30 hours). Setting the first and second temperature conditions and the respective reaction times within the above ranges makes it possible to improve the degree of polymerization and the physical properties.

Note that a raw material mixture may be polycondensated using a publicly-known solid phase polymerization method (for example, a method that heat-treat a prepolymer resin under an inert atmosphere of nitrogen or the like or under vacuum at a temperature range of 100 to 400° C. for 1 to 30 hours, or the like) after a prepolymer is obtained through melt polymerization or the like in which the raw material mixture is reacted under the first temperature condition, the prepolymer was cooled down and solidified, thereafter is pulverized into a powder shape or a flake shape.

In addition a polymerization reaction apparatus that can be used in conducting such a polycondensation (preferably, melt polymerization) is not particularly limited, and for example, a publicly-known reaction apparatus used for reacting a high viscosity fluid can be used as appropriate. Such a reaction apparatus includes, for example, stirred tank-type polymerization reaction apparatuses having stirring apparatuses equipped with stirring blades of various shapes of anchor type, multi-stage type, spiral band type, spiral shaft type, and the like, or shapes obtained by modifying these types, or mixing apparatuses such as a kneader, a roll mill, and a Bunbury mixer used for kneading resins, and the like.

In this way, by polycondensating the raw material mixture, it is possible to obtain a liquid crystal polyester (II) in which a linear liquid crystal polymer chain comprising the monomers (A) to (C) is bonded via the monomer (D).

[Liquid Crystal Polymer Particles]

Liquid crystal polymer particles according to the present invention are liquid crystal polymer particles that are insoluble in the solvent, have a melting point of 270° C. or more, and have a cumulative distribution 50% diameter D₅₀ of 20 μm or less and a cumulative distribution 90% diameter D₉₀ of 2.5 times or less the D₅₀ in a particle size distribution. Note that herein being “insoluble” in a solvent is such that after 4 g of a liquid crystal polyester is mixed with 16 g of N-methyl-2-pyrrolidone (NMP), followed by heating at 100° C. for 2 hours, a solid component of the liquid crystal polyester is visually observed, as described above.

In addition, the liquid crystal polymer particles according to the present invention are fine particles that comprise a liquid crystal polymer and have the above-described specific particle size distribution. Such a particle size distribution of liquid crystal polymer particles can be measured using a laser diffraction particle size analyzer. In such a particle size distribution, the “cumulative distribution 50% diameter D₅₀ (hereinafter referred to as “D₅₀”)” represents the value of particle diameter with which the cumulative distribution from the small particle diameter side reaches 50%, and the “cumulative distribution 90% diameter D₉₀ (hereinafter referred to as “D₉₀”)” represents the value of particle diameter with which the cumulative distribution from the small particle diameter side reaches 90%. In addition, in such a particle size distribution, the “modal diameter Dₚ (hereinafter referred to as “Dₚ”) “represents the value of particle diameter with the highest frequency.

Such liquid crystal polymer particles satisfy conditions that D₅₀ in a particle size distribution is 20 μm or less, and D₉₀ is 2.5 times or less the D₅₀. Such D₅₀ is preferably 0.1 μm or more (more preferably 1 μm or more, further preferably 3 μm or more, and particularly preferably 5 μm or more), and is preferably 15 μm or less (more preferably 12 μm or less, and further preferably 10 μm or less). In addition, D₉₀ is preferably 1.1 times or more (more preferably 1.2 times or more, and further preferably 1.3 times or more) the D₃₀, and is preferably 2.2 times or less (more preferably 2.0 times or less, and further preferably 1.8 times or less) the D₅₀.

By adjusting values of D₅₀ and D₉₀ which are parameters in such a particle size distribution of liquid crystal polymer particles within the above ranges, it is possible to reduce the dissipation factor while suppressing the surface roughness of the resin film when the liquid crystal polymer particles are added to the resin film. Note that the values of D₅₀ and D₉₀ can be adjusted by a method for pulverizing the liquid crystal polymer particles, the condition on sieving after the pulverization, and the like.

In addition, in such liquid crystal polymer particles, the ratio of Dₚ to D₅₀ in the particle size distribution is preferably 0.7 or more and 1.3 or less, more preferably 0.75 times or more and 1.25 times or less, and more preferably 0.8 times or more and 1.2 times or less. By adjusting such a ratio of Dₚ to D₅₀ within the above range, it is possible to reduce the dissipation factor while suppressing the surface roughness of the resin film when the liquid crystal polymer particles are added to the resin film. Note that the value of Dₚ can be adjusted by the method for pulverizing liquid crystal polymer particles, the condition on sieving after the pulverization, and the like in the same manner as that for the values of D₅₀ and D₉₀.

The liquid crystallinity of the liquid crystal polymer can be checked, for example, by using a polarized light microscope manufactured by Olympus Corporation (under the trade name of BH-2) equipped with a hot stage for microscopes manufactured by Mettler Toledo (under the trade name of FP82HT), or the like and by heating and melting the liquid crystal polymer on the microscope hot-stage and observing the presence or absence of optical anisotropy.

In addition, the melting point of such liquid crystal polymer particles is 270° C. or more, as the lower limit value thereof, is preferably 280° C. or more, more preferably 290° C. or more, and further preferably 300° C. or more, and as the upper limit value thereof, is preferably 370° C. or less, preferably 360° C. or less, and further preferably 350° C. or less. By setting the melting point of the liquid crystal polymer within the above numerical value range, it is possible to improve the heat resistance of the resin film obtained by adding the liquid crystal polymer particles. Note that in the Specification, the melting point of the liquid crystal polymer is in compliance with the test methods of ISO 11357 and ASTM D3418, and can be measured using a differential scanning calorimeter (DSC) manufactured by Hitachi High-Tech Science Corporation, or the like.

In addition, the dissipation factor (measurement frequency: 10 GHz) of the liquid crystal polymer particles is preferably 0.001 or less, more preferably 0.0009 or less, further preferably 0.0008 or less, and particularly preferably 0.0007 or less. This value is a measured value of the dissipation factor in an in-plane direction of an injection-molded article of the liquid crystal polymer particles. Note that this injection-molded article is a flat plate-shaped test piece of 30 mm×30 mm×0.4 mm(thickness).

The water absorption rate of the liquid crystal polymer particles is preferably 0.05% or less, more preferably 0.04% or less, and further preferably 0.03% or less. The water absorption rate was a value obtained by measuring a weight of the test piece in a dry state and a weight of the test piece in a water-absorbed state after the test piece is immersed in water for 24 hours, and dividing a difference between the weight in the water-absorbed state and the weight in the dry state by the weight in the dry state. When the liquid crystal polymer particles have the above low water absorption rate, it is possible to stably express the low-dielectric performance in actual use as well.

In addition, the composition of the liquid crystal polymer, which is a raw material of such liquid crystal polymer particles, is not particularly limited, but it is preferable that the liquid crystal polymer contain a structural unit (vi) derived from an aromatic hydroxycarboxylic acid described later, a structural unit (vii) derived from an aromatic dicarboxylic acid described later, and a structural unit (viii) derived from an aromatic diol described later. Note that the liquid crystal polymer, which is the raw material of such liquid crystal polymer particles, may further contain another structural unit other than the structural units (vi) to (viii), which will be described later.

In addition, the liquid crystal polymer particles are preferably particles comprising a polycondensate of a raw material mixture that comprises the following monomers (E) to (G):

[monomer (E)] a bifunctional aromatic hydroxycarboxylic acid;

[monomer (F)] a bifunctional aromatic dicarboxylic acid; and

[monomer (G)] a bifunctional aromatic diol, and that satisfies one of the following conditions (I) to (II):

[condition (I)] the raw material mixture does not contain a compound for forming a bent structural unit; and

[condition (II)] in a case where the raw material mixture contains a compound for forming a bent structural unit, a content of the compound is less than 20% by mol relative to a total amount of the monomers (E) to (G) because it becomes possible to more efficiently allow the liquid crystal polymer particles to have a melting point within the above range and be insoluble in a solvent. Note that such a polycondensate of a raw material mixture comprising the monomers (E) to (G) becomes a liquid crystal polyester (hereinafter, this liquid crystal polyester is sometimes referred to simply as the “liquid crystal polyester (III)”) as is clear from the types of the monomers.

As such a bifunctional aromatic hydroxycarboxylic acid as the monomer (E), a publicly-known aromatic hydroxycarboxylic acid that can be used in the formation of liquid crystal polyesters can be used as appropriate. In addition, such a bifunctional aromatic hydroxycarboxylic acid as the monomer (E) may be an aromatic hydroxycarboxylic acid itself, or may be a derivative such as an acylated compound or an ester derivative thereof. Such a monomer (E) includes, for example, a compound represented by a formula (6):

HO—Ar¹⁰—COOH (6)

[in the formula (6), Ar¹⁰ represents a group selected from the group consisting of a phenylene group, a biphenylene group, a 4,4′-isopropylidenediphenylene group, a naphthylene group, an anthrylene group, and a phenanthrylene group each of which may have a substituent], and an acylated compound, an ester derivative, and a silylated compound thereof. As Ar¹⁰ in such a formula, particularly a phenylene group and a naphthylene group are preferable. In addition, as Ar¹⁰ in the formula, 2,6-naphthylene, 2,7-naphthylene, 1,4-naphthylene, 1,5-naphthylene, 1,4-phenylene, and 4,4′-biphenylene are preferable, from the viewpoint of liquid crystallinity, high crystallinity, high heat resistance, thermoplasticity, low dielectricity, low dissipation factor, solvent resistance, and low thermal expansion. Note that the substituent that the group represented by Ar¹⁰ may have includes a hydrogen atom, an alkyl group, an alkoxy group, an aryl group, a fluorine atom, and the like. As such an alkyl group, an alkyl group having 1 to 10 (more preferably 1 to 5) carbon atoms is preferable. In addition, such an alkyl group may be a linear alkyl group or a branched alkyl group. Moreover, as the alkoxy group, an alkoxy group having 1 to 10 (more preferably 1 to 5) carbon atoms is preferable. Furthermore, as the aryl group, an aryl group having 6 to 20 (more preferably 6 to 15) carbon atoms is preferable.

In addition, among such monomers (E), 6-hydroxy-2-naphthoic acid (HNA), and an acylated compound, an ester derivative, a silylated compound, and the like thereof are preferable.

In addition, as such a bifunctional aromatic dicarboxylic acid as the monomer (F), a publicly-known aromatic dicarboxylic acid that can be used in the formation of liquid crystal polyesters can be used as appropriate. Such a bifunctional aromatic dicarboxylic acid as the monomer (F) may be an aromatic dicarboxylic acid itself, or may be a derivative such as a mixed acid anhydride, an ester derivative or an acid halide thereof. Such a monomer (F) includes, for example, a compound represented by a formula (7):

HOOC—Ar¹¹—COOH (7)

[in the formula (7), Ar^{1l} represents a group selected from the group consisting of a phenylene group, a biphenylene group, a 4,4′-isopropylidenediphenylene group, a naphthylene group, an anthrylene group, and a phenanthrylene group each of which may have a substituent], and a mixed acid anhydride, an ester derivative, and an acid halide thereof. As Ar¹¹ in such a formula (7), particularly a phenylene group and a naphthylene group are preferable. Moreover, as Ar¹¹ in the formula, a group selected from the group consisting of 1,4-phenylene, 1,4-naphthylene, 1,5-naphthylene, 2,6-naphthylene, 4,4′-biphenylene, and 2,7-naphthylene is preferable, from the viewpoint of liquid crystallinity, high crystallinity, high heat resistance, thermoplasticity, low dielectricity, low dissipation factor, solvent resistance, and low thermal expansion. Note that the substituent that the group represented by Ar^{1l} may have includes the same as those described as the substituents that the group represented by Ar¹⁰ may have (the same applies to the preferable ones).

In addition, among such monomers (F), terephthalic acid, isophthalic acid, 2,6-naphthalenedicarboxylic acid, 2,7-naphthalenedicarboxylic acid, 1,4-naphthalenedicarboxylic acid, 1,5-naphthalenedicarboxylic acid, and 4,4′-biphenyldicarboxylic acid, and mixed acid anhydrides, ester derivatives, acid halides, and the like of these are preferable.

In addition, as such a bifunctional aromatic diol as the monomer (G), a publicly-known aromatic diol that can be used in the formation of liquid crystal polyesters can be used as appropriate. Such a bifunctional aromatic diol as the monomer (G) may be an aromatic diol itself, or may be a derivative such as an acylated compound, an ester derivative or a silylated compound thereof. Such a monomer (G) includes, for example, a compound represented by a formula (8):

HO—Ar¹²—OH (8)

[in the formula (8), Ar¹² represents a group selected from the group consisting of a phenylene group, a biphenylene group, a 4,4′-isopropylidenediphenylene group, a naphthylene group, an anthrylene group, and a phenanthrylene group each of which may have a substituent], and an acylated compound, an ester derivative, and a silylated compound thereof. As Ar¹² in such a formula (8), particularly, a phenylene group and a biphenylene group are preferable. In addition, as Ar¹² in the formula, a group selected from the group consisting of 1,4-phenylene, 1,4-naphthylene, 1,5-naphthylene, 2,6-naphthylene, 4,4′-biphenylene, and 2,7-naphthylene is preferable, from the viewpoint of liquid crystallinity, high crystallinity, high heat resistance, thermoplasticity, low dielectricity, low dissipation factor, solvent resistance, and low thermal expansion. Note that the substituent that the group represented by Ar¹² may have includes the same as those described as the substituents that the group represented by Ar¹⁰ may have (the same applies to the preferable ones).

Among such monomers (G), 4,4-dihydroxybiphenyl (BP), hydroquinone (HQ), methylhydroquinone (MeHQ), and 4,4′-isopropylidenediphenol (BisPA), and acylated compounds, ester derivatives, silylated compounds, and the like of these are preferable. In addition, among these, 4,4-dihydroxybiphenyl (BP) and hydroquinone (HQ), and acylated compounds, ester derivatives, and silylated compound of these are more preferably used.

In addition, such a liquid crystal polyester (III) contains a structural unit (vi) derived from the above monomer (E), a structural unit (vii) derived from the above monomer (F), and a structural unit (viii) derived from the above monomer (G), as is clear from the types of the monomers contained in the raw material mixture.

As such a structural unit (vi) derived from the monomer (E), a structural unit represented by a formula (vi):

—O—Ar¹⁰—CO— (vi)

[in the formula (vi), Ar¹⁰ has the same meaning as Ar¹⁰ in the above formula (6) (the same applies to the preferable ones).] is preferable. Note that such a liquid crystal polyester (III) may contain only one type of the structural unit (vi) or may contain two or more types of the structural unit (vi).

In addition, as the structural unit (vii) derived from the above monomer (F), a structural unit represented by a formula (vii):

—OC—Ar¹¹—CO (vii)

[in the formula (vii), Ar¹¹ has the same meaning as Ar¹¹ in the above formula (7) (the same applies to the preferable ones).] is preferable. Note that such a liquid crystal polyester (III) may contain only one type of the structural unit (vii) or may contain two or more types of the structural unit (vii).

As the structural unit (viii) derived from the monomer (G), a structural unit represented by a formula (viii):

—O—Ar¹²—O— (viii)

[in the formula (viii), Ar¹² has the same meaning as Ar¹² in the above formula (8) (the same applies to the preferable ones),] is preferable. Note that such a liquid crystal polyester (III) may contain only one type of the structural unit (viii) or may contain two or more types of the structural unit (viii).

In addition, in such a liquid crystal polyester (III), the composition percentage (% by mol) of the structural unit (vi) relative to the total amount of the structural units is not particularly limited, but the lower limit value thereof is preferably 40% by mol or more, more preferably 45% by mol or more, further preferably 50% by mol or more, and particularly preferably 55% by mol or more, and the upper limit value thereof is preferably 80% by mol or less, more preferably 75% by mol or less, further preferably 70% by mol or less, and particularly preferably 65% by mol or less. In a case where two or more of such a structural unit (vi) are contained, the total molar ratio of these only has to be within the above range of the composition percentage.

In addition, in such a liquid crystal polyester (III), the composition percentage (% by mol) of the structural unit (vii) relative to the total amount of the structural units is not particularly limited, but the lower limit value thereof is preferably 10% by mol or more, more preferably 12.5% by mol or more, further preferably 15% by mol or more, and particularly preferably 17.5% by mol or more, and the upper limit value thereof is preferably 30% by mol or less, more preferably 27.5% by mol or less, further preferably 25% by mol or less, and even more preferably 22.5% by mol or less. In a case where two or more of such a structural unit (vii) are contained, the total molar ratio of these only has to be within the above range of the composition percentage.

In addition, in such a liquid crystal polyester (III), the composition percentage (% by mol) of the structural unit (viii) relative to the total amount of the structural units is not particularly limited, but the lower limit value thereof is preferably 10% by mol or more, more preferably 12.5% by mol or more, further preferably 15% by mol or more, and particularly preferably 17.5% by mol or more, and the upper limit value thereof is preferably 30% by mol or less, more preferably 27.5% by mol or less, further preferably 25% by mol or less, and particularly preferably 22.5% by mol or less. Note that it is preferable that the composition percentage of the structural unit (vi) and the composition percentage of the structural unit (viii) be substantially equal to each other (the structural unit (vi)≈the structural unit (viii)).

In addition, in the production of the liquid crystal polyester (III), another monomer other than the above monomers (E) to (G) may be used as appropriate. Hence, the liquid crystal polyester (III) may further contain another structural unit derived from another monomer other than the above monomers (E) to (G) (another structural unit other than the structural units (vi) to (viii)). Such another structural unit is not particularly limited as long as the structural unit is derived from another monomer that is other than the monomers (E) to (G) which provide the above structural units (vi) to (viii) and that has polymerizability to be polymerizable with the monomers which provide the above structural units (vi) to (viii). Such a polymerizable group includes, for example, a hydroxy group, a carboxyl group, an amino group, an ester group, an amide group, an acid anhydride group, an acid halide group, a silyl ether group, an isocyanate group, an isothiocyanate group, a chlorocarbonate group, an epoxy group, a chlorosulfonyl group, and the like. The monomer that provides another structural unit has one or more of these polymerizable groups, and preferably two or more of these. In a case where the monomer contains two or more polymerizable groups, these polymerizable groups may be the same or may be different. Only one type of such other structural unit may be contained, or two or more types thereof may be contained.

Such other structural unit that can be contained in the liquid crystal polyester (III) includes, for example, a structural unit (ix) represented by the following formula (ix):

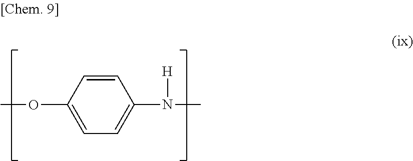

a structural unit (x) represented by the following formula (x):

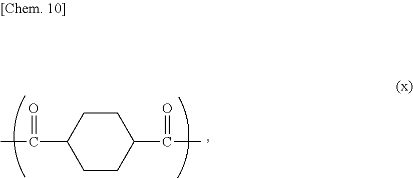

and the like. Note that monomers that can form such a structural unit (ix) include acetaminophen (AAP), p-aminophenol, 4′-acetoxyacetanilide, and acylated compounds, ester derivatives, silylated compounds and the like of these. In addition, monomers that can form the structural unit (x) include 1,4-cyclohexanedicarboxylic acid (CHDA), and mixed acid anhydrides, ester derivatives, acid halides, and the like of these.

The composition percentage (% by mol) of the other structural unit relative to the total amount of the structural units of the liquid crystal polyester (III) may be set as appropriate depending on the composition percentages of the structural units (vi) to (viii). Specifically, the composition percentage of each structural unit may be set as appropriate such that the monomer ratio (molar ratio) between carboxyl groups and hydroxy groups and/or amine groups in monomer feeds becomes in a range of approximately 1:1.

It is preferable that the raw material compounds containing the monomers (E) to (G) (which may further contain the other monomer as necessary, as described above) which are used in the preparation of the liquid crystal polyester (III) satisfy any of the following conditions (I) to (II):

[condition (I)] the raw material compounds do not contain a compound for forming a bent structural unit, and

[condition (II)] in a case where the raw material compounds contain a compound for forming a bent structural unit, a content of the compound is less than 20% by mol relative to a total amount of the monomers (E) to (G). That is, in the raw material compounds containing the monomers (E) to (G), the content of the compound for forming a bent structural unit is preferably 0% by mol or more and less than 20% by mol (more preferably 0 to 15% by mol, and further preferably 0 to 10% by mol) relative to the total amount of the monomers (E) to (G). If the content of the compound for forming a bent structural unit is more than the upper limit, there is a tendency that the solubility of the liquid crystal polyester (III) in a solvent becomes high, so that the liquid crystal polymer particles comprising the liquid crystal polyester (III) become soluble in the solvent. Note that the “compound for forming a bent structural unit” mentioned herein is the same as that described in the above-described “liquid crystal polyester that is soluble in a solvent”. In addition, in a case where at least one of the monomers (E) to (G) in the raw material compounds is a compound for forming a bent structural unit (including, for example, the case where the monomer (F) is isophthalic acid, the case where the monomer (G) is catechol, resorcinol, or 2,3-dihydroxynaphthalene, and the like), the content of the compound for forming a bent structural unit is preferably less than 20% by mol relative to the total amount of the monomers (E) to (G).

In addition, the method for preparing liquid crystal polymer particles comprising such a liquid crystal polyester (III) is not particularly limited, but a method that is capable of polycondensating raw material compounds containing the monomers (E) to (G) (which may further contain the other monomer as necessary, as described above) to form particles of the polymer may be employed as appropriate. As the method for polycondensating raw material compounds, for example, a two-stage polymerization method in which a prepolymer is prepared through melt polymerization, and then this is further subjected to solid phase polymerization may be employed.

Such melt polymerization is preferably conducted under reflux of acetic acid by blending the monomers (E) to (G) and the other monomer, which is added as necessary, in a predetermined blending ratio to 100% by mol in total, with the presence of acetic anhydride of 1.05 to 1.15 molar equivalents relative to all the hydroxyl groups that these monomers have, from the viewpoint that it becomes possible to more efficiently form the liquid crystal polyester (III).

In addition, in the case of employing the above-described two-stage polymerization method, a method in which the prepolymer obtained by the melt polymerization as described above is cooled and solidified, and thereafter is pulverized into a powder shape or a flake shape, and then this is polymerized by a publicly-known solid phase polymerization method (for example, a method that heat-treats the prepolymer resin at a temperature range of 200 to 350° C. for 1 to 30 hours under an inert atmosphere such as nitrogen or under vacuum, or the like) can be favorably used, from the viewpoint of making the shape of the polymer thus obtained into particles. Note that such solid phase polymerization may be conducted while agitating the prepolymer, or may be conducted while leaving the prepolymer to stand.

In addition, in such polycondensation, a catalyst may be used, or does not have to be used. As such a catalyst, a conventionally publicly-known catalyst for polymerizing polyester (for example, metallic salt catalysts such as magnesium acetate, stannous acetate, tetrabutyl titanate, lead acetate, sodium acetate, potassium acetate, antimony trioxide; organic compound catalysts such as nitrogen-containing heterocyclic compounds such as N-methylimidazole, and the like) can be used as appropriate. The amount of such a catalyst to be used is not particularly limited, but is preferably 0.0001 to 0.1 parts by mass relative to 100 parts by mass of the total amount of the monomers.

In addition, a polymerization reaction apparatus that can be used for conducting such a polycondensation is not particularly limited, and for example, a publicly-known reaction apparatus that is used for reaction of high viscosity fluids may be used as appropriate. Such a reaction apparatus includes, for example, stirred tank-type polymerization reaction apparatuses having stirring apparatuses equipped with stirring blades of various shapes of anchor type, multi-stage type, spiral band type, spiral shaft type, and the like, or shapes obtained by modifying these types, or mixing apparatuses such as a kneader, a roll mill, and a Bunbury mixer used for kneading resins, and the like.

In addition, after the liquid crystal polyester (III) in the form of particles is obtained, it is preferable to conduct a process of collecting the particles through a sieve having predetermined apertures after conducting a pulverizing process using a publicly-known apparatus such as a jet mill, such that the particles satisfy conditions of a cumulative distribution 50% diameter D₅₀ of 20 μm or less and a cumulative distribution 90% diameter D₉₀ of 2.5 times or less the D₅₀ in a particle size distribution. Note that it is preferable to pulverize the liquid crystal polyester (III) in the form of particles obtained through polycondensation, at a pulverizing pressure of 0.1 to 10 MPa using a jet mill from the viewpoint of obtaining particles that satisfy the above-described conditions. In addition, the aperture of the sieve is not particularly limited, but is preferably 0.1 to 100 μm. It is possible to more efficiently obtain particles that satisfy conditions of a cumulative distribution 50% diameter D₅₀ of 20 μm or less and a cumulative distribution 90% diameter D₉₀ of 2.5 times or less the D₅₀ in a particle size distribution by conducting the process of collecting the particles through a sieve having predetermined apertures after conducting a pulverizing process using a publicly-known apparatus such as a jet mill after the liquid crystal polyester (III) in the form of particles is obtained under such conditions.

[Regarding the Composition and the Like of Each Component in the Composite]

The composite of the present invention comprises: the above liquid crystal polyester that is soluble in a solvent; and the above liquid crystal polymer particles.

In such a composite, the content of the liquid crystal polymer particles is preferably 5 to 80 parts by mass (more preferably 10 to 70 parts by mass, further preferably 15 to 60 parts by mass, and particularly preferably 20 to 50 parts by mass) relative to 100 parts by mass of the above liquid crystal polyester that is soluble in a solvent. When the content of the liquid crystal polymer particles is within the above range, it is possible to further reduce the dissipation factor while making the surface roughness of the resin film sufficiently small when the resin film is produced using the composite. In addition, setting the content of the liquid crystal polymer particles within the above range makes it possible to obtain a slurry having a higher dispersibility and thus makes it possible to form a film having a higher uniformity when a mixture of a solvent and the composite is prepared.

Note that such a composite may contain another component other than the above liquid crystal polyester that is soluble in a solvent and the above liquid crystal polymer particles. Such other component is not particularly limited, but includes, for example, a colorant, a dispersant, a plasticizer, an antioxidant, a curing agent, a flame retardant, a heat stabilizer, an ultraviolet absorber, an antistatic agent, a surfactant, and the like.

In addition, such a composite (polyester composite) may be molded for use by a conventionally publicly-known method. Such a molding method includes, for example, press molding, foam molding, injection molding, extrusion molding, punch molding, and the like. In addition, it is possible to prepare a slurry composition, which will be described later, using the composite of the present invention, and to use and mold the slurry composition. A molded body of the composite produced in this way may be processed into various shapes depending on the usage. Such shapes of the molded body are not limited, but include, for example, a film shape, a sheet shape, a metal-clad laminate shape, and a plate shape. Note that it is preferable to make the composite of the present invention into a molded body having a film shape or a metal-clad laminate shape because it becomes possible to further reduce the dissipation factor as described above, and such a molded body can be used favorably for various substrates and the like. In addition, since the composite of the present invention makes it possible to further reduce the dissipation factor as described above, the composite can be favorably used, for example, as a material for forming a substrate used in high frequency high speed communication devices (millimeter-wave radars for automobiles, antennas for smartphones, and the like), a material for forming substrates for substitution of resin substrates used in the existing FCCL, and the like.

<Slurry Composition>

A slurry composition of the present invention comprises: the above composite of the present invention; and a solvent.

As such a solvent, the same solvents as described as those in which the liquid crystal polyester can be dissolved in the above-described “liquid crystal polyester that is soluble in a solvent” are preferable. In addition, as such a solvent, an aprotic solvent (more preferably N,N′-dimethylformamide, N,N′-dimethylacetamide, or N-methyl-2-pyrrolidone (NMP), and particularly preferably N-methyl-2-pyrrolidone (NMP)) is preferable.

In such a slurry composition, the content of the composite is not particularly limited, but is preferably 1 to 80% by mass (more preferably 5 to 50% by mass). When the content is within the above range, it becomes possible to more favorably use the slurry composition as a liquid material (a varnish or the like) for producing a resin film (such a resin film may be used as a resin layer stacked on a substrate) or the like. Note that in a case where such a slurry composition is used as a material for forming a film, the mass of the solvent is preferably an amount being 2 to 20 times the mass of the composite. The method for preparing such a slurry composition is not particularly limited, and a publicly-known method can be employed as appropriate.

In addition, such a slurry composition can be favorably used for producing molded bodies having various shapes comprising the composite. For example, it is also possible to easily produce a composite having a film shape by applying such a slurry composition onto various substrates to obtain an applied film, thereafter removing the solvent from the applied film, and curing the applied film. The method of such application is not particularly limited, but a publicly-known method such as a spin coating method, a roller coating method, a spray coating method, a curtain coating method, a dip coating method, a slot coating method, a dropping method, a gravure printing method, a screen printing method, a relief printing method, a die coating method, a curtain coating method, an inkjet method, or the like can be employed as appropriate, for example. Moreover, the method for removing the solvent from the applied film is also not particularly limited, but a method that heats the applied film while reducing the pressure is preferably employed. As the temperature condition in this method, a temperature equal to or more than the boiling point of the solvent is preferably employed. In addition, the method for curing the applied film is not particularly limited, but a method that cures the applied film by heating the applied film at a temperature of around 100 to 500° C. for 0.1 to 10 hours may be employed, for example.

In addition, depending on the usage, such a slurry composition may further contain additive components such as antioxidants, ultraviolet absorbers·hindered amine light stabilizers, nucleating agents·clarifying agents, inorganic fillers (glass fibers, hollow glass spheres, talc, mica, alumina, titania, silica, and the like), heavy metal deactivators·additives for filled polymers, flame retardants, processability improvers·lubricants/water dispersion type stabilizers, permanent antistatic agents, toughness improvers, surfactants, carbon fibers, and the like, for example.

<Film>

A film of the present invention comprises the above composite of the present invention. The method for preparing such a film is not particularly limited, but it is preferable to employ a method that uses the above slurry composition of the present invention, applies the slurry composition onto various substrates to obtain an applied film, thereafter removes the solvent from the applied film, and cures the applied film.

In addition, the film of the present invention only has to comprise the above composite of the present invention, and the film thickness of the film is not particularly limited, but is preferably 1 to 1000 μm (more preferably 5 to 300 μm) from the viewpoint of the mechanical properties and the handling.

Note that since such a film of the present invention has a low dissipation factor derived from the properties of the composite, the film can be favorably used as a material for a flexible printed circuit board (FPC) (a material for a flexible copper-clad laminate (FCCL)) and the like, for example.

<Metal-Clad Laminate>

A metal-clad laminate of the present invention comprises: a metal foil; and a resin layer stacked on the metal foil, wherein the resin layer is a layer comprising the above composite of the present invention.

Such a metal foil is not particularly limited, and a publicly-known metal foil on which a resin layer can be stacked can be used as appropriate. Such a metal foil includes, for example, a copper foil, copper alloy foils of phosphor bronze, red brass, brass, nickel silver, titanium copper, Corson alloy, and the like, a stainless steel foil, an aluminum foil, an iron foil, an iron alloy foil, a nickel foil, a nickel alloy foil, and the like. As such a metal foil, a copper foil is particularly preferable. In addition, such a copper foil may be a rolled copper foil or an electrolytic copper foil, but a rolled copper foil is preferable. In such a copper foil, a roughening treatment may be conducted on a surface onto which the resin layer is to be stacked. Such a roughening treatment can be conducted through a copper-cobalt-nickel alloy plating process, a copper-nickel-phosphorus alloy plating process, or the like as described in Japanese Unexamined Patent Application Publication No. 2014-141736 (JP 2014-141736 A).

In addition, on the surface of the copper foil onto which the resin layer is to be stacked (in a case where a roughening treatment is conducted, the roughened surface), a heat-resistant layer or an anti-rust layer may be formed. The method for forming such a heat-resistant layer or anti-rust layer is not particularly limited, and a publicly-known method (for example, a method such as a nickel plating process described in JP 2014-141736 A) can be employed as appropriate. Moreover, on the surface of the copper foil onto which the resin layer is to be stacked (in a case where a roughening treatment is conducted, the roughened surface, or in a case where a heat-resistant layer or an anti-rust layer is formed, the surfaces of these layers), it is preferable that a surface-treatment layer made of a silane coupling agent containing nitrogen atoms be formed. This further improves adhesion between the copper foil and the polyester resin layer. Such a silane coupling agent containing nitrogen atoms is not particularly limited, and a publicly-known silane coupling agent (for example, a silane coupling agent exemplified in paragraph of Japanese Unexamined Patent Application Publication No. 2017-071193, and the like) can be used as appropriate.

In addition, as such a copper foil, for example, rolled copper foils in which fine roughening particles are formed in base foils excellent in bending properties such as HA foil, HA-V2 foil, TPC foil (tough pitch foil), HS foil, and surface-treated foil (BHY treatment, BHYX treatment, and GHY5 treatment), manufactured and sold by JX Nippon Mining & Metals Corporation, and electrolytic copper foils (for example, those manufactured by JX Nippon Mining & Metals Corporation under the trade names of JXUT, JTCLC, JTCSLC, JXLP, JXEFL, and the like) can be used. In addition, the thickness of such a copper foil only has to be a thickness that is applicable to a copper-clad laminate, and is not particularly limited.

In addition, in the present invention, the resin layer is stacked on the metal foil. Then, such a resin layer is a layer comprising the above composite of the present invention. The thickness of such a resin layer comprising the composite is not particularly limited, but is preferably 1 to 1000 μm (more preferably 5 to 300 μm). Setting the thickness within the above range makes it possible to achieve a layer having higher uniformity and higher mechanical strength, and there is also a tendency that higher easiness in production like easier removal of the solvent in production of a resin layer using the slurry composition, for example, is achieved.

In addition, the method for producing such a metal-clad laminate is not particularly limited, but a method for obtaining a metal-clad laminate by forming an applied film of the above slurry composition of the present invention on a surface of a metal foil, and thereafter heating and curing the applied film can be favorably employed.

In such a method for producing a metal-clad laminate, the method for forming an applied film of the slurry composition on the metal foil is not particularly limited, and a publicly-known method can be employed as appropriate. For example, a method for forming an applied film of the slurry composition on the metal foil by applying the slurry composition by employing a publicly-known coating method (a spin coating method, a roller coating method, a spray coating method, a curtain coating method, a dip coating method, a slot coating method, a dropping method, a gravure printing method, a screen printing method, a relief printing method, a die coating method, a curtain coating method, an inkjet method, or the like) may be employed.

In addition, the method for heating and curing such an applied film is also not particularly limited, a publicly-known method that can be used in forming a resin layer using a resin solution (varnish) can be employed as appropriate (for example, a method that cures an applied film by heating the applied film at a temperature of around 100 to 500° C. for 0.1 to 10 hours may be employed). Note that before the applied film is heated and cured, it is preferable to conduct a step of removing the solvent from the applied film. Such a solvent removing step is also not particularly limited, and can be conducted by setting conditions as appropriate depending on the type of the solvent (for example, a method for removing the solvent from the applied film by leaving the applied film to stand at a temperature condition of 30 to 400° C. for around 0.1 to 100 hours may be employed). In this way, the metal-clad laminate of the present invention can be produced.

Note that since the composite of the present invention has a low dissipation factor, the metal-clad laminate of the present invention comprising the resin layer comprising such a composite can be favorably used for high frequency usage, millimeter-wave radar usage, and the like. In addition, the metal-clad laminate of the present invention can be favorably used for flexible copper-clad laminate (FCCL) and the like, for example.

### EXAMPLES

The present invention will be described more specifically below based on Examples and Comparative Examples; however, the present invention is not limited to Examples below.

First, methods for evaluating properties of liquid crystal polymer particles A1 obtained in Synthesis Example 1, liquid crystal polyesters B1 to B6 obtained in Examples and the like, and films obtained in Examples and the like will be described.

<Measurement of Particle Diameter Distribution of Liquid Crystal Polymer Particles A1>

The particle size distribution of the liquid crystal polymer particles A1 obtained in Synthesis Example 1 was measured using a laser diffraction particle size analyzer (LS 13 320 dry system manufactured by Beckman Coulter Inc., equipped with tornado dry powder module). D₅₀, D₉₀, and Dₚ, which are parameters indicating the particle size distribution, were obtained as calculation result from measured data.

<Evaluation of Liquid Crystallinities of Liquid Crystal Polymer Particles A1 and Liquid Crystal Polyesters B1 to B6>

The liquid crystal polyester obtained in each Example was observed using polarized light microscopy to evaluate the presence or absence of liquid crystallinity. Specifically, the liquid crystal polyester was heated and melted on a microscope hot-stage, and thereafter the presence or absence of optical anisotropy was observed to check liquid crystallinity, using a polarized light microscope manufactured by Olympus Corporation (under the trade name of “BH-2”) equipped with a hot stage for microscopes manufactured by Mettler Toledo (under the trade name of FP82HT).

<Measurement of Number Average Molecular Weights of Liquid Crystal Polyesters B1 to B6>

GPC (gel permeation chromatography) measurement was conducted on the liquid crystal polyester obtained in each Example to obtain the number average molecular weight (Mn). Specifically, an NMP solution of the liquid crystal polyester (the content of the liquid crystal polyester: 20 wt %) was prepared, one drop of the NMP solution (about 15 mg) was dissolved in 1.0 mL of a GPC eluent (a solution obtained by adding 10 mmol of lithium bromide to 1.0 L of N,N-dimethylacetamide), and analysis was conducted under a condition of a flow speed of 0.5 ml/min using EcoSEC HLC-8320GPC (GPC column:TOSOH TSKgel super AW 2500×2+TOSOH TSKgel super AW 3000×1+TOSOH TSKgel super AW 4000×1+TOSOH TSKgel guardcolumn super AW-L×1) manufactured by TOSOH. The analysis was conducted using a refractometer (RI) and an ultraviolet analyzer (UV: 275 nm) together as detectors, and the number average molecular weight (Mn) was obtained from RI data.

<Measurement of Melting Points of Liquid Crystal Polymer Particles A1 and Liquid Crystal Polyesters B1 to B6>

DSC measurement was conducted on each of the liquid crystal polymer particles A1 and the liquid crystal polyester B1 to B6 to obtain the melting point. Specifically, the melting point was measured using a differential scanning calorimeter (DSC) manufactured by Hitachi High-Tech Science Corporation in compliance with the test methods of ISO 11357 and ASTM D3418. Note that in this measurement, the peak of the endothermic peak obtained by increasing the temperature from room temperature to 300 to 380° C. at a rate of temperature increase of 10° c./min to completely melt the polymer, thereafter lowering the temperature to 30° C. at a rate of 10° c./min, and further increasing the temperature to 360° C. at a rate of 10° c./min was obtained as the melting point (Tm).

<Measurement of Glass Transition Points of Liquid Crystal Polyesters B1 to B6>

Waveform processing was conducted on the transition point of data obtained in the previous melting point (Tm) measurement on each of the liquid crystal polyesters B1 to B6 obtained in Examples to obtain the glass transition point (Tg).

<Evaluation of Solubilities of Liquid Crystal Polymer Particles A1 and Liquid Crystal Polyesters B1 to B6>

By using each of the liquid crystal polymer particles A1 (particles composed of the liquid crystal polyester) and the liquid crystal polyesters B1 to B6, 4 g of the liquid crystal polyester was mixed with 16 g of N-methyl-2-pyrrolidone (NMP), the mixture liquid thus obtained was heated at 100° C. for 2 hours, and thereafter it was visually checked whether or not the solid component of the polyester remained in the mixture liquid. When no solid component remained, the liquid crystal polyester was evaluated to have solubility in a solvent, while when even a small amount of the solid component remained, the liquid crystal polyester was evaluated to have no solubility in a solvent. Note that such an evaluation on the liquid crystal polyesters B1 to B6 was conducted together when a resin solution was prepared in a step of preparing a slurry composition, which will be described later.

<Method for Measuring Dissipation Factor (Df) and Relative Permittivity (Dk) of Film>

The dissipation factor (Df, tan δ) and the relative permittivity (Dk, εr) were measured by using a sample piece obtained by drying the film (vertical side (length): 76 mm, horizontal side (width): 52 mm, film thickness: 20 μm) obtained in each Example or the like at 85° C. for 2 hours and employing the split post dielectric resonator (SPDR) method. In addition, such a measurement was conducted in a laboratory adjusted to be under an environment of 23° C. and a relative humidity of 50%, and trade name “Vector Network Analyzer PNA-X N5247A” manufactured by Keysight Technologies International Japan G. K. (the former Agilent Technologies, Inc.) was used as a measuring device. In addition, in the measurement, the test piece (obtained by leaving the polyester film after being dried at 85° C. for 2 hours to stand in the laboratory adjusted to 23° C. and a relative humidity of 50% for 24 hours) was set in the SPDR dielectric resonator which was the measuring device, and the respective actual measured values of the dissipation factor (tan δ) and the relative permittivity (εr) were obtained with the frequency being set to 10 GHz. Such a measurement of the actual measured values was conducted four times in total, average values of these were obtained as the values of the dissipation factor (tan δ) and the relative permittivity (εr) of the film obtained in each Example or the like. In this way, as the values of the dissipation factor (tan δ) and the relative permittivity (εr), the average values of the actual measured values obtained by four times of measurement were employed.

[Raw Material Compounds Used in Each Example or the Like]

Abbreviated names and the like of compounds (monomers) used in Synthesis Example and Examples and the like, which will be described later, are shown below. In the descriptions of Examples and the like below (including Tables), the compounds are expressed using the abbreviated names described below.
HNA: 6-Hydroxy-2-naphthoic acid (produced by Ueno Fine Chemicals Industry, Ltd.)
NADA: 2,6-Naphthalenedicarboxylic acid (produced by Ueno Fine Chemicals Industry, Ltd.)
IPA: Isophthalic acid (produced by Mitsubishi Gas Chemical Company, Inc.)
3AP: 3-Aminophenol (produced by Aldrich)
4AP: 4-Aminophenol (produced by Aldrich)
8A2HN: 8-Amino-2-naphthol (produced by Aldrich)
ODA: 4,4′-Oxydianiline (produced by Seika Corporation)
BP: 4,4-Dihydroxybiphenyl (produced by Honshu Chemical Industry Co., Ltd.)
TPA: Terephthalic acid (produced by Mitsui Chemicals)
DHTPA: 2,5-Dihydroxyterephthalic acid (produced by Tokyo Chemical Industry Co., Ltd.)
MHQ: Methylhydroquinone (produced by Seiko Chemical Co., Ltd.)
BTCA: 1,3,5-Benzenetricarboxylic acid (produced by Tokyo Chemical Industry Co., Ltd.)
HIPA: 5-Hydroxyisophthalic acid (produced by Tokyo Chemical Industry Co., Ltd.)
BTOH: 1,3,5-Trihydroxybenzene (anhydride) (produced by Tokyo Chemical Industry Co., Ltd.)
DHBA: 3,5-Dihydroxybenzoic acid (produced by Tokyo Chemical Industry Co., Ltd.)
DCDPE: Diphenyl ether-4,4′-dicarboxylic acid (produced by Tokyo Chemical Industry Co., Ltd.)

Note that all “IPA”, “3AP”, “8A2HN”, and “DCDPE” are compounds for forming a bent structural unit.

### Synthesis Example 1: Synthesis of Liquid Crystal Polymer Particles

Into a polymerization container having stirring blades, HNA (60% by mol), BP (20% by mol), TPA (15.5% by mol), and NADA (4.5% by mol) were added, and thereafter potassium acetate and magnesium acetate were charged as catalysts, reduction of pressure-injection of nitrogen on the polymerization container was conducted three times to conduct purging with nitrogen, then acetic anhydride (1.08 molar equivalent relative to hydroxyl groups) was further added, the temperature was increased to 150° C., and then acetylation reaction was conducted for 2 hours in a reflux state.

After the completion of the acetylation, the temperature of the polymerization container in an acetic acid distillation state was increased at 0.5° c./min, and once the temperature of the melt in the container reached 310° C., the polymer was taken out, and cooled and solidified. The polymer thus obtained was pulverized into a size that passed through a sieve having an aperture of 2.0 mm to obtain a prepolymer.

Next, the temperature of the prepolymer thus obtained was increased from room temperature to 295° C. over 14 hours with a heater in an oven manufactured by Yamato Scientific Co., Ltd., and the temperature was then held at 295° C. for 1 hour to conduct solid phase polymerization. Thereafter, the temperature was naturally dissipated at room temperature to obtain a liquid crystal polymer A (having an average particle diameter of 80 μm). The liquid crystal polymer A was heated and melted on a microscope hot-stage using the polarized light microscope manufactured by Olympus Corporation (under the trade name of BH-2) equipped with the hot stage for microscopes manufactured by Mettler Toledo (under the trade name of FP82HT), and it was confirmed that the liquid crystallinity was exhibited from the presence or absence of optical anisotropy.

Next, the powder of the liquid crystal polymer A (having an average particle diameter of 80 μm) was pulverized using a jet mill, Nano Jetmizer NJ-50 model manufactured by Aishin Nano Technologies Co., Ltd., for 15 minutes under conditions of a pulverizing pressure of 1.4 MPa, an amount of a resin supplied of 120 g/h to obtain a pulverized product. Subsequently, the pulverized product thus obtained was subjected to a sieve having an aperture of 20 μm using a vibrating sieve with ultrasonic wave generator, and the pulverized product passed through the sieve was collected to obtain liquid crystal polymer particles A1 having a substantially spherical shape.

Note that since D₅₀ of such liquid crystal polymer particles A1 was 4.8 μm and D₉₀ thereof was 8.6 μm, D₉₀/D₅₀ was 1.8, while Dₚ was 6.0 μm. In addition, the melting point of the liquid crystal polymer particles A1 was 319° C. Note that after 4.0 g of such liquid crystal polymer particles A1 was added to 16.0 g of NMP and heated at 100° C. for 2 hours, when the mixture liquid thus obtained was visually observed, the presence of particles (solid component) was observed, and it was confirmed that the liquid crystal polymer was insoluble in a solvent.

### Example 1

<Step of Preparing a Liquid Crystal Polyester B1>

Into a 500-ml separable flask, HNA (0.1176 mol, 22.12 g), NADA (0.0784 mol, 16.94 g), 8A2HN (0.0784 mol, 12.48 g), acetic anhydride (0.27 mol, 28.0 g) were added to obtain a mixture (a step of preparing a mixture). Thereafter, a heating treatment was conducted on the mixture thus obtained in which after the mixture was heated at 200° C. for 1 hour, the temperature was increased to 330° C., and the mixture was held at 330° C. for 30 minutes. After such a heating treatment, the resin (liquid crystal polyester B1) thus obtained was taken out of the separable flask. Note that the yield of the obtained resin (liquid crystal polyester B1) was 44.1 g (yield 95%).

As a result of evaluating the physical properties of the liquid crystal polyester B1 obtained in this way, it was confirmed that the liquid crystal polyester B1 exhibited liquid crystallinity, and that the liquid crystal polyester B1 had a glass transition temperature (Tg) of 167° C. and a melting point (Tm) of 293° C. In addition, as a result of the GPC measurement, the number average molecular weight (Mn) of the liquid crystal polyester B1 was 62710.

<Step of Preparing a Slurry Composition>

Next, 4.0 g of the liquid crystal polyester B1 was added to 16.0 g of NMP, followed by heating at 100° C. for 2 hours to prepare a resin solution having a resin concentration of 20% by mass (note that in this resin solution, since no solid component of the liquid crystal polyester was observed, it was confirmed that the liquid crystal polyester obtained as described above was soluble in a solvent).

Subsequently, to the resin solution, 1.2 g of the liquid crystal polymer particles A1 obtained in Synthesis Example 1 was added to obtain a slurry composition (a composition composed of the solvent composed of NMP, the liquid crystal polyester that is soluble in a solvent, and the liquid crystal polymer particles). Note that the content of the liquid crystal polymer particles A1 relative to the total amount of the liquid crystal polyester B1 and the liquid crystal polymer particles A1 was 23% by mass, and in the case where the content of the liquid crystal polyester B1 was assumed to be 100 parts by mass, the content of the liquid crystal polymer particles A1 was 30 parts by mass.

<Step of Preparing a Film>

The slurry composition (mixture liquid) obtained as described above was applied by spin-coating on a surface of a glass substrate [large-sized glass slide (manufactured by Matsunami Glass Ind., Ltd., trade name “S9213”, vertical side: 76 mm, horizontal side 52 m, thickness 1.3 mm)] such that the thickness of an applied film after heating became 20 μm, so that the applied film was formed on the glass substrate. Thereafter, the glass substrate with the applied film formed thereon was placed on a hot plate at 70° C. and left to stand for 0.5 hours to evaporate and remove the solvent from the applied film (solvent removal process). After such a solvent removal process was conducted, the glass substrate with the applied film formed thereon was placed into an inert oven (the flow rate of nitrogen: 5 L/min), was heated at a temperature condition of 80° C. for 0.5 hours and was subsequently heated at a temperature condition of 240° C. for 60 minutes under a nitrogen atmosphere to bake the applied film, and was then cooled down to 80° C. under a nitrogen atmosphere to obtain a polyester-coated glass in which the glass substrate was coated with a thin film composed of polyester.

Next, the polyester-coated glass thus obtained was immersed into a hot water at 90° C., and the polyester film was peeled off from the glass substrate to obtain a polyester film (a film having a size of a vertical side of 76 mm, a horizontal side of 52 mm, and a thickness of 20 μm). Regarding the obtained polyester film, the evaluation results of the dielectric property and the like are shown in Table 1.

### Example 2

<Step of Preparing a Liquid Crystal Polyester B2>

A liquid crystal polyester B2 was prepared by employing the same method as the <step of preparing a liquid crystal polyester B1> employed in Example 1 except that DHTPA was further added into the 500-ml separable flask such that the content proportion of the DHTPA became 0.7 mol relative to 100 mol (converted value) of the total molar amount of the monomers composed of HNA, NADA, and 8A2HN in the step of preparing a mixture. As a result of evaluating the physical properties of the liquid crystal polyester B2 obtained in this way, it was confirmed that the liquid crystal polyester B2 exhibited liquid crystallinity, and that the liquid crystal polyester B2 had a glass transition temperature (Tg) of 175° C. and a melting point (Tm) of 304° C. In addition, as a result of the GPC measurement, the number average molecular weight (Mn) of the liquid crystal polyester B2 was 66320.

<Steps of Preparing a Slurry Composition and a Film>

A slurry composition and a film were prepared by employing the same methods as the <step of preparing a slurry composition> and the <step of preparing a film> employed in Example 1 except that the liquid crystal polyester B2 obtained as described above was used instead of the liquid crystal polyester B1. Regarding the obtained polyester film, the evaluation results of the dielectric property and the like are shown in Table 1. Note that since no solid component of the liquid crystal polyester B2 was observed when the resin solution having a resin concentration of 20% by mass was prepared in the step of preparing a slurry composition, it was confirmed that the liquid crystal polyester B2 was also soluble in a solvent.

### Example 3

<Step of Preparing a Liquid Crystal Polyester B3>

A liquid crystal polyester B3 was prepared by employing the same method as the <step of preparing a liquid crystal polyester B1> employed in Example 1 except that 0.0784 mol of 3AP was used instead of 8A2HN in the step of preparing a mixture. As a result of evaluating the physical properties of the liquid crystal polyester B3 obtained in this way, it was confirmed that the liquid crystal polyester B3 exhibited liquid crystallinity, and that the liquid crystal polyester B3 had a glass transition temperature (Tg) of 159° C. and a melting point (Tm) of 309° C. In addition, as a result of the GPC measurement, the number average molecular weight (Mn) of the liquid crystal polyester B3 was 127420.

<Steps of Preparing a Slurry Composition and a Film>

A slurry composition and a film were prepared employing the same methods as the <step of preparing a slurry composition> and the <step of preparing a film> employed in Example 1 except that the liquid crystal polyester B3 obtained as described above was used instead of the liquid crystal polyester B1. Regarding the obtained polyester film, the evaluation results of the dielectric property and the like are shown in Table 1. Note that since no solid component of the liquid crystal polyester B3 was observed when the resin solution having a resin concentration of 20% by mass was prepared in the step of preparing a slurry composition, it was confirmed that the liquid crystal polyester B3 was also soluble in a solvent.

### Example 4

<Step of Preparing a Liquid Crystal Polyester B4>

A liquid crystal polyester B4 was prepared by employing the same method as the <step of preparing a liquid crystal polyester B2> employed in Example 2 except that 0.0784 mol of 3AP was used instead of 8A2HN in the step of preparing a mixture. As a result of evaluating the physical properties of the liquid crystal polyester B4 obtained in this way, it was confirmed that the liquid crystal polyester B4 exhibited liquid crystallinity, and that the liquid crystal polyester B4 had a glass transition temperature (Tg) of 157° C. and a melting point (Tm) of 320° C. In addition, as a result of the GPC measurement, the number average molecular weight (Mn) of the liquid crystal polyester B4 was 115240.

<Steps of Preparing a Slurry Composition and a Film>

A slurry composition and a film were prepared by employing the same methods as the <step of preparing a slurry composition> and the <step of preparing a film> employed in Example 1 except that the liquid crystal polyester B4 obtained as described above was used instead of the liquid crystal polyester B1. Regarding the obtained polyester film, the evaluation results of the dielectric property and the like are shown in Table 1. Note that since no solid component of the liquid crystal polyester B4 was observed when the resin solution having a resin concentration of 20% by mass was prepared in the step of preparing a slurry composition, it was confirmed that the liquid crystal polyester B4 was also soluble in a solvent.

### Example 5

<Step of Preparing a Liquid Crystal Polyester B5>

A liquid crystal polyester B5 was prepared by employing the same method as the <step of preparing a liquid crystal polyester B1> employed in Example 1 except that the step of preparing a mixture was changed to a step of obtaining a mixture by adding HNA (0.259 mol, 48.71 g), IPA (0.129 mol, 21.50 g), 4AP (0.129 mol, 14.12 g), and acetic anhydride (0.52 mol, 52.85 g) into a 500-ml separable flask. As a result of evaluating the physical properties of the liquid crystal polyester B5 obtained in this way, it was confirmed that the liquid crystal polyester B5 exhibited liquid crystallinity, and that the liquid crystal polyester B5 had a glass transition temperature (Tg) of 143° C. and a melting point (Tm) of 307° C. In addition, as a result of the GPC measurement, the number average molecular weight (Mn) of the liquid crystal polyester B5 was 168990.

<Steps of Preparing a Slurry Composition and a Film>

A slurry composition and a film were prepared by employing the same methods as the <step of preparing a slurry composition> and the <step of preparing a film> employed in Example 1 except that the liquid crystal polyester B5 obtained as described above was used instead of the liquid crystal polyester B1. Regarding the obtained polyester film, the evaluation results of the dielectric property and the like are shown in Table 1. Note that since no solid component of the liquid crystal polyester B5 was observed when the resin solution having a resin concentration of 20% by mass was prepared in the step of preparing a slurry composition, it was confirmed that the liquid crystal polyester B5 was also soluble in a solvent.

### Example 6

<Step of Preparing a Liquid Crystal Polyester B6>

A liquid crystal polyester B6 was prepared by employing the same method as the <step of preparing a liquid crystal polyester B1> employed in Example 1 except that the step of preparing a mixture was changed to a step of obtaining a mixture by adding HNA (0.240 mol, 45.16 g), IPA (0.120 mol, 19.93 g), 4AP (0.060 mol, 6.55 g), ODA (0.060 mol, 12.01 g), and acetic anhydride (0.48 mol, 49.00 g) into a 500-ml separable flask. As a result of evaluating the physical properties of the liquid crystal polyester B6 obtained in this way, it was confirmed that the liquid crystal polyester B6 exhibited liquid crystallinity, and that the liquid crystal polyester B6 had a glass transition temperature (Tg) of 150° C. and a melting point (Tm) of 340° C.

<Steps of Preparing a Slurry Composition and a Film>

A slurry composition and a film were prepared by employing the same methods as the <step of preparing a slurry composition> and the <step of preparing a film> employed in Example 1 except that the liquid crystal polyester B6 obtained as described above was used instead of the liquid crystal polyester B1. Regarding the obtained polyester film, the evaluation results of the dielectric property and the like are shown in Table 1. Note that since no solid component of the liquid crystal polyester B6 was observed when the resin solution having a resin concentration of 20% by mass was prepared in the step of preparing a slurry composition, it was confirmed that the liquid crystal polyester B6 was also soluble in a solvent.

### Example 7

<Step of Preparing a Liquid Crystal Polyester B7>

A liquid crystal polyester B7 was prepared by employing the same method as the <step of preparing a liquid crystal polyester B1> employed in Example 1 except that 0.0784 mol of IPA was used instead of NADA and 0.0784 mol of MHQ was used instead of 8A2HN in the step of preparing a mixture. As a result of evaluating the physical properties of the liquid crystal polyester B7 obtained in this way, it was confirmed that the liquid crystal polyester B7 exhibited liquid crystallinity, and that the liquid crystal polyester B7 had a glass transition temperature (Tg) of 109° C. and a melting point (Tm) of 284° C. In addition, as a result of the GPC measurement, the number average molecular weight (Mn) of the liquid crystal polyester B7 was 121500.

<Steps of Preparing a Slurry Composition and a Film>

A slurry composition and a film were prepared by employing the same methods as the <step of preparing a slurry composition> and the <step of preparing a film> employed in Example 1 except that the liquid crystal polyester B7 obtained as described above was used instead of the liquid crystal polyester B1. Regarding the obtained polyester film, the evaluation results of the dielectric property and the like are shown in Table 1. Note that since no solid component of the liquid crystal polyester B7 was observed when the resin solution having a resin concentration of 20% by mass was prepared in the step of preparing a slurry composition, it was confirmed that the liquid crystal polyester B7 was also soluble in a solvent.

### Example 8

<Step of Preparing a Liquid Crystal Polyester B8>

A liquid crystal polyester B8 was prepared by employing the same method as the <step of preparing a liquid crystal polyester B2> employed in Example 2 except that 0.0784 mol of IPA was used instead of NADA, 0.0784 mol of MHQ was used instead of 8A2HN, and DHTPA was added such that the content proportion of the DHTPA became 1 mol relative to 100 mol (converted value) of the total molar amount of the monomers composed of HNA, IPA, and MHQ in the step of preparing a mixture. As a result of evaluating the physical properties of the liquid crystal polyester B8 obtained in this way, it was confirmed that the liquid crystal polyester B8 exhibited liquid crystallinity, and that the liquid crystal polyester B8 had a glass transition temperature (Tg) of 120° C. and a melting point (Tm) of 285° C. In addition, as a result of the GPC measurement, the number average molecular weight (Mn) of the liquid crystal polyester B8 was 131220.

<Steps of Preparing a Slurry Composition and a Film>

A slurry composition and a film were prepared by employing the same methods as the <step of preparing a slurry composition> and the <step of preparing a film> employed in Example 1 except that the liquid crystal polyester B8 obtained as described above was used instead of the liquid crystal polyester B1. Regarding the obtained polyester film, the evaluation results of the dielectric property and the like are shown in Table 1. Note that since no solid component of the liquid crystal polyester B8 was observed when the resin solution having a resin concentration of 20% by mass was prepared in the step of preparing a slurry composition, it was confirmed that the liquid crystal polyester B8 was also soluble in a solvent.

### Example 9

<Step of Preparing a Liquid Crystal Polyester B9>

A liquid crystal polyester B9 was prepared by employing the same method as the <step of preparing a liquid crystal polyester B2> employed in Example 2 except that 0.0784 mol of IPA was used instead of NADA, 0.0826 mol of MHQ was used instead of 8A2HN, BTCA was used instead of DHTPA, and the BTCA was added such that the content proportion of the BTCA became 1 mol relative to 100 mol (converted value) of the total molar amount of the monomers composed of HNA, IPA, and MHQ in the step of preparing a mixture. As a result of evaluating the physical properties of the liquid crystal polyester B9 obtained in this way, it was confirmed that the liquid crystal polyester B9 exhibited liquid crystallinity, and that the liquid crystal polyester B9 had a glass transition temperature (Tg) of 116° C. and a melting point (Tm) of 287° C. In addition, as a result of the GPC measurement, the number average molecular weight (Mn) of the liquid crystal polyester B9 was 116610.

<Steps of Preparing a Slurry Composition and a Film>

A slurry composition and a film were prepared by employing the same methods as the <step of preparing a slurry composition> and the <step of preparing a film> employed in Example 1 except that the liquid crystal polyester B9 obtained as described above was used instead of the liquid crystal polyester B1. Regarding the obtained polyester film, the evaluation results of the dielectric property and the like are shown in Table 1. Note that since no solid component of the liquid crystal polyester B9 was observed when the resin solution having a resin concentration of 20% by mass was prepared in the step of preparing a slurry composition, it was confirmed that the liquid crystal polyester B9 was also soluble in a solvent.

### Example 10

<Step of Preparing a Liquid Crystal Polyester B10>

A liquid crystal polyester B10 was prepared by employing the same method as the <step of preparing a liquid crystal polyester B2> employed in Example 2 except that 0.0784 mol of IPA was used instead of NADA, 0.0798 mol of MHQ was used instead of 8A2HN, HIPA was used instead of DHTPA, the HIPA was added such that the content proportion of the HIPA became 1 mol relative to 100 mol (converted value) of the total molar amount of the monomers composed of HNA, IPA, and MHQ in the step of preparing a mixture. As a result of evaluating the physical properties of the liquid crystal polyester B10 obtained in this way, it was confirmed that the liquid crystal polyester B10 exhibited liquid crystallinity, and that the liquid crystal polyester B10 had a glass transition temperature (Tg) of 116° C. and a melting point (Tm) of 286° C. In addition, as a result of the GPC measurement, the number average molecular weight (Mn) of the liquid crystal polyester B10 was 116510.

<Steps of Preparing a Slurry Composition and a Film>

A slurry composition and a film were prepared by employing the same methods as the <step of preparing a slurry composition> and the <step of preparing a film> employed in Example 1 except that the liquid crystal polyester B10 obtained as described above was used instead of the liquid crystal polyester B1. Regarding the obtained polyester film, the evaluation results of the dielectric property and the like are shown in Table 1. Note that since no solid component of the liquid crystal polyester B10 was observed when the resin solution having a resin concentration of 20% by mass was prepared in the step of preparing a slurry composition, it was confirmed that the liquid crystal polyester B10 was also soluble in a solvent.

### Example 11

<Step of Preparing a Liquid Crystal Polyester B11>

A liquid crystal polyester B11 was prepared by employing the same method as the <step of preparing a liquid crystal polyester B2> employed in Example 2 except that 0.0826 mol of IPA was used instead of NADA, 0.0784 mol of MHQ was used instead of 8A2HN, BTOH was used instead of DHTPA, and the BTOH was added such that the content proportion of the BTOH became 1 mol relative to 100 mol (converted value) of the total molar amount of the monomers composed of HNA, IPA, and MHQ in the step of preparing a mixture. As a result of evaluating the physical properties of the liquid crystal polyester B11 obtained in this way, it was confirmed that the liquid crystal polyester B11 exhibited liquid crystallinity, and that the liquid crystal polyester B11 had a glass transition temperature (Tg) of 112° C. and a melting point (Tm) of 285° C. In addition, as a result of the GPC measurement, the number average molecular weight (Mn) of the liquid crystal polyester B11 was 111910.

<Steps of Preparing a Slurry Composition and a Film>

A slurry composition and a film were prepared by employing the same methods as the <step of preparing a slurry composition> and the <step of preparing a film> employed in Example 1 except that the liquid crystal polyester B11 obtained as described above was used instead of the liquid crystal polyester B1. Regarding the obtained polyester film, the evaluation results of the dielectric property and the like are shown in Table 1. Note that since no solid component of the liquid crystal polyester B11 was observed when the resin solution having a resin concentration of 20% by mass was prepared in the step of preparing a slurry composition, it was confirmed that the liquid crystal polyester B11 was also soluble in a solvent.

### Example 12

<Step of Preparing a Liquid Crystal Polyester B12>

A liquid crystal polyester B12 was prepared by employing the same method as the <step of preparing a liquid crystal polyester B2> employed in Example 2 except that 0.0840 mol of IPA was used instead of NADA, 0.0784 mol of MHQ was used instead of 8A2HN, DHBA was used instead of DHTPA, and the DHBA was added such that the content proportion of the DHBA became 1 mol relative to 100 mol (converted value) of the total molar amount of the monomers composed of HNA, IPA, and MHQ in the step of preparing a mixture. As a result of evaluating the physical properties of the liquid crystal polyester B12 obtained in this way, it was confirmed that the liquid crystal polyester B12 exhibited liquid crystallinity, and that the liquid crystal polyester B12 had a glass transition temperature (Tg) of 113° C. and a melting point (Tm) of 283° C. In addition, as a result of the GPC measurement, the number average molecular weight (Mn) of the liquid crystal polyester B12 was 112730.

<Steps of Preparing a Slurry Composition and a Film>

A slurry composition and a film were prepared by employing the same methods as the <step of preparing a slurry composition> and the <step of preparing a film> employed in Example 1 except that the liquid crystal polyester B12 obtained as described above was used instead of the liquid crystal polyester B1. Regarding the obtained polyester film, the evaluation results of the dielectric property and the like are shown in Table 1. Note that since no solid component of the liquid crystal polyester B12 was observed when the resin solution having a resin concentration of 20% by mass was prepared in the step of preparing a slurry composition, it was confirmed that the liquid crystal polyester B12 was also soluble in a solvent.

### Example 13

<Step of Preparing a Liquid Crystal Polyester B13>

A liquid crystal polyester B13 was prepared by employing the same method as the <step of preparing a liquid crystal polyester B1> employed in Example 1 except that 0.0784 mol of DCDPE was used instead of NADA and 0.0784 mol of MHQ was used instead of 8A2HN in the step of preparing a mixture. As a result of evaluating the physical properties of the liquid crystal polyester B13 obtained in this way, it was confirmed that the liquid crystal polyester B13 exhibited liquid crystallinity, and that the liquid crystal polyester B13 had a glass transition temperature (Tg) of 116° C. and a melting point (Tm) of 280° C. In addition, as a result of the GPC measurement, the number average molecular weight (Mn) of the liquid crystal polyester B13 was 138680.

<Steps of Preparing a Slurry Composition and a Film>

A slurry composition and a film were prepared by employing the same methods as the <step of preparing a slurry composition> and the <step of preparing a film> employed in Example 1 except that the liquid crystal polyester B13 obtained as described above was used instead of the liquid crystal polyester B1. Regarding the obtained polyester film, the evaluation results of the dielectric property and the like are shown in Table 1. Note that since no solid component of the liquid crystal polyester B13 was observed when the resin solution having a resin concentration of 20% by mass was prepared in the step of preparing a slurry composition, it was confirmed that the liquid crystal polyester B13 was also soluble in a solvent.

### Example 14

<Step of Preparing a Liquid Crystal Polyester B8>

A liquid crystal polyester B14 was prepared by employing the same methods as the <step of preparing a liquid crystal polyester B2> employed in Example 2 except that 0.0784 mol of DCDPE was used instead of NADA, 0.0784 mol of MHQ was used instead of 8A2HN, and DHTPA was added such that the content proportion of the DHTPA became 1 mol relative to 100 mol (converted value) of the total molar amount of the monomer composed of HNA, DCDPE, and MHQ in the step of preparing a mixture. As a result of evaluating the physical properties of the liquid crystal polyester B14 obtained in this way, it was confirmed that the liquid crystal polyester B14 exhibited liquid crystallinity, and that the liquid crystal polyester B14 had a glass transition temperature (Tg) of 107° C. and a melting point (Tm) of 281° C. In addition, as a result of the GPC measurement, the number average molecular weight (Mn) of the liquid crystal polyester B14 was 149770.

<Steps of Preparing a Slurry Composition and a Film>

A slurry composition and a film were prepared by employing the same methods as the <step of preparing a slurry composition> and the <step of preparing a film> employed in Example 1 except that the liquid crystal polyester B14 obtained as described above was used instead of the liquid crystal polyester B1. Regarding the obtained polyester film, the evaluation results of the dielectric property and the like are shown in Table 1. Note that since no solid component of the liquid crystal polyester B14 was observed when the resin solution having a resin concentration of 20% by mass was prepared in the step of preparing a slurry composition, it was confirmed that the liquid crystal polyester B14 was also soluble in a solvent.

### Comparative Example 1

<Steps of Preparing a Slurry Composition and a Film>

A slurry composition and a film were prepared by employing the same methods as the <step of preparing a slurry composition> and the <step of preparing a film> employed in Example 1 except that a commercially-available polyimide (trade name “SPIXAREA GR003” produced by SOMAR Corporation) was used instead of the liquid crystal polyester B1. Note that the obtained film was a polyimide film. Regarding the film, the evaluation results of the dielectric property and the like are shown in Table 1.

Note that the dispersibility of the liquid crystal polymer particles A1 in the slurry composition obtained in each Example or the like was evaluated as follows. Specifically, in the case where when the slurry composition was visually observed, it was confirmed that the particles A1 were dispersed, and further when the applied film was formed in the step of preparing a film, it was confirmed that the surface of the applied film was uniform and no unevenness or repellency or uneven application occurred, it was determined that the dispersibility of the particles A1 was high (favorable). On the other hand, when the above conditions were not satisfied, it was determined that the dispersibility was low. In this way, the dispersibility was evaluated. The obtained results are shown together in Table 1. In addition, the molar ratio of the monomers used in preparation of each of the liquid crystal polyesters B1 to B14 used in Examples is also shown in Table 1.

TABLE 1

| | Compositions of liquid | | Film | Dissipation | |
|---|---|---|---|---|---|
| | crystal polyesters B1 to B6 | Dispersibility | thickness | factor | Permittivity |
| | (molar ratio) | of particles A1 | of film | (Df) | (Dk) |
| Example 1 | HNA/NADA/8A2HN | High | 20 μm | 0.0023 | 3.01 |
| | (1.5/1.0/1.0) | (Favorable) | | | |
| Example 2 | HNA/NADA/8A2HN/DHTPA | High | 20 μm | 0.0022 | 3.05 |
| | (1.5/1.0/1.0/0.025) | (Favorable) | | | |
| Example 3 | HNA/NADA/3AP | High | 20 μm | 0.0023 | 3.05 |
| | (1.5/1.0/1.0) | (Favorable) | | | |
| Example 4 | HNA/NADA/3AP/DHTPA | High | 20 μm | 0.0022 | 3.06 |
| | (1.5/1.0/1.0/0.025) | (Favorable) | | | |
| Example 5 | HNA/IPA/4AP | High | 20 μm | 0.0028 | 3.07 |
| | (2.0/1.0/1.0) | (Favorable) | | | |
| Example 6 | HNA/IPA/4AP/ODA | High | 20 μm | 0.0023 | 3.32 |
| | (2.0/1.0/0.5/0.5) | (Favorable) | | | |
| Example 7 | HNA/IPA/MHQ | High | 20 μm | 0.00159 | 3.36 |
| | (1.5/1.0/1.0) | (Favorable) | | | |
| Example 8 | HNA/IPA/MHQ/DHTPA | High | 20 μm | 0.00146 | 3.33 |
| | (1.5/1.0/1.0/0.035) | (Favorable) | | | |
| Example 9 | HNA/IPA/MHQ/BTCA | High | 20 μm | 0.00204 | 3.38 |
| | (1.5/1.0/1.054/0.036) | (Favorable) | | | |
| Example 10 | HNA/IPA/MHQ/HIPA | High | 20 μm | 0.00161 | 3.40 |
| | (1.5/1.0/1.018/0.036) | (Favorable) | | | |
| Example 11 | HNA/IPA/MHQ/BTOH | High | 20 μm | 0.00186 | 3.40 |
| | (1.5/1.054/1.0/0.036) | (Favorable) | | | |
| Example 12 | HNA/IPA/MHQ/DHBA | High | 20 μm | 0.00187 | 3.37 |
| | (1.5/1.018/1.0/0.036) | (Favorable) | | | |
| Example 13 | HNA/DCDPE/MHQ | High | 20 μm | 0.00139 | 3.41 |
| | (1.5/1.0/1.0) | (Favorable) | | | |
| Example 14 | HNA/DCDPE/MHQ/DHTPA | High | 20 μm | 0.00131 | 3.32 |
| | (1.5/1.0/1.0/0.035) | (Favorable) | | | |
| Comparative | Polyimide | High | 20 μm | 0.0140 | 3.05 |
| Example 1 | (Commercial Product) | (Favorable) | | | |

As is clear from the results shown in Table 1, it was confirmed that all the films obtained in Examples 1 to 14 (films each comprising the composite of the liquid crystal polyester and the liquid crystal polymer particles) had lower values of dissipation factors. In addition, it was also confirmed that the slurry compositions obtained in Examples 1 to 14 had high dispersibilities of liquid crystal polymer particles.

### Examples 15 to 28

First, the same slurry compositions as the slurry compositions prepared respectively in Examples were prepared by employing the same method as the method employed in Examples 1 to 14 described above. Next, a laminate in which a copper foil was coated with a thin film comprising the composite of the liquid crystal polyester and the liquid crystal polymer particles was prepared using each slurry composition thus obtained.

Specifically, each obtained slurry composition was applied by spin-coating on the surface of a copper foil [a rolled copper foil manufactured by JX Nippon Mining & Metals Corporation (a copper foil having a surface treated with BHYX treatment) of 10 cm square having a thickness of 12 μm] such that the thickness of an applied film after heating became 20 μm, so that the applied film of the slurry composition was formed on the copper foil. Thereafter, the copper foil with the applied film formed thereon was placed on a hot plate at 70° C. and was left to stand for 0.5 hours to evaporate and remove the solvent from the applied film (solvent removal process). After such a solvent removal process was conducted, the copper foil with the applied film formed thereon was placed into an inert oven (the flow rate of nitrogen: 5 L/min), was heated at a temperature condition of 80° C. for 0.5 hours under a nitrogen atmosphere, was then heated at a temperature condition of 240° C. for 60 minutes, and was thereafter cooled down to 80° C. under a nitrogen atmosphere to obtain a laminate in which the copper foil was coated with the thin film comprising the composite of the liquid crystal polyester and the liquid crystal polymer particles.

In this way, in Examples 15 to 28, laminates in each of which the copper foil was coated with the thin film comprising the composite were prepared respectively using the same slurry compositions as the slurry compositions prepared in Examples 1 to 14, and thereafter, the sticking force between the copper foil and the thin film was evaluated using each of the obtained laminates. Specifically, cuts (vertical and horizontal 11 directions, an interval of width of 1 mm) were made in the thin film comprising the composite in the laminate with a cutter knife, and thereafter a cross-cut test (grid tape test, commonly called: 100-square peeling test) was conducted using an adhesive tape [Cellotape (registered trademark) manufactured by Nichiban Co., Ltd.] to evaluate the sticking force between the copper foil and the thin film comprising the composite. As a result of such an evaluation test of sticking force, in all the laminates obtained in Examples 15 to 28 (in which the thin films comprising the composites were formed on the copper foils respectively using the same slurry compositions as the slurry compositions prepared in Examples 1 to 14), there was no peeling, lifting, or the like of the thin film at all, and it was thus confirmed that the sticking force between the copper foil and the thin film comprising the composite was significantly high. From such results, it was confirmed that when the slurry compositions prepared in Examples 1 to 14 were used, the sticking force between the copper foil and the thin film comprising the composite became significantly high.

### INDUSTRIAL APPLICABILITY

As described above, the present invention makes it possible to provide a composite that enables a slurry having a high dispersibility to be obtained and is capable of having a lower dissipation factor, a slurry composition using the same, a film comprising the composite, and a metal-clad laminate using the composite. Such a composite of the present invention can be favorably used, for example, as a material for forming a substrate used in high frequency high speed communication devices (millimeter-wave radars for automobiles, antennas for smartphones, and the like), a material for forming a substrate for substitution of resin substrates used in the existing FCCL, and the like.

1. A composite comprising:
a liquid crystal polyester that is soluble in a solvent; and
liquid crystal polymer particles that are insoluble in a solvent, have a melting point of 270° C. or more, and have a cumulative distribution 50% diameter D₅₀ of 20 μm or less and a cumulative distribution 90% diameter D₉₀ of 2.5 times or less the D₅₀ in a particle size distribution.

2. The composite according to claim 1, wherein
the liquid crystal polyester that is soluble in a solvent is a liquid crystal polyester comprising the following monomers (A) to (C):
[monomer (A)] a bifunctional aromatic hydroxycarboxylic acid;
[monomer (B)] a bifunctional aromatic dicarboxylic acid; and
[monomer (C)] at least one compound selected from the group consisting of a bifunctional aromatic diol, a bifunctional aromatic hydroxyamine, and a bifunctional aromatic diamine, in which
at least one of the monomer (B) and the monomer (C) contains a compound for forming a bent structural unit, and
a content of the compound for forming a bent structural unit is 20 to 40% by mol relative to a total molar amount of the monomers (A) to (C).

3. The composite according to claim 1, wherein
the liquid crystal polyester that is soluble in a solvent is a liquid crystal polyester wherein
a linear liquid crystal polymer chain comprising the following monomers (A) to (C):
[monomer (A)] a bifunctional aromatic hydroxycarboxylic acid;
[monomer (B)] a bifunctional aromatic dicarboxylic acid; and
[monomer (C)] at least one compound selected from the group consisting of a bifunctional aromatic diol, a bifunctional aromatic hydroxyamine, and a bifunctional aromatic diamine, in which at least one of the monomer (B) and the monomer (C) contains a compound for forming a bent structural unit, and a content of the compound for forming a bent structural unit is 20 to 40% by mol relative to a total molar amount of the monomers (A) to (C), is bonded via the following monomer (D):
[monomer (D)] an aromatic compound having 3 to 8 functional groups of at least one kind selected from the group consisting of a hydroxy group, a carboxy group, and an amino group, and
a content proportion of the monomer (D) is 0.01 to 10 mol relative to 100 mol of the total molar amount of the monomers (A) to (C).

4. The composite according to claim 1, wherein
the liquid crystal polymer particles are particles comprising a polycondensate of a raw material mixture that comprises the following monomers (E) to (G):
[monomer (E)] a bifunctional aromatic hydroxycarboxylic acid;
[monomer (F)] a bifunctional aromatic dicarboxylic acid; and
[monomer (G)] a bifunctional aromatic diol, and that satisfies one of the following conditions (I) to (II):
[condition (I)] the raw material mixture does not contain a compound for forming a bent structural unit; and
[condition (II)] in a case where the raw material mixture contains a compound for forming a bent structural unit, a content of the compound is less than 20% by mol relative to a total amount of the monomers (E) to (G).

5. A slurry composition comprising:
the composite according to claim 1; and
a solvent.

6. A film comprising:
the composite according to claim 1.

7. A metal-clad laminate comprising:
a metal foil; and
a resin layer stacked on the metal foil, wherein
the resin layer is a layer comprising the composite according to claim 1.
